(19) United States
(12) Patent Application Publication
(10) Pub. No.: US 2026/0190513 A1
(43) Pub. Date: Jul. 2, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Chih-Kuan YU, Tainan City (TW); Feng-Chi HUNG, Chu-Bei City (TW); Wen-I HSU, Tainan City (TW); Jen-Cheng LIU, Hsin-Chu City (TW); Dun-Nian YAUNG, Taipei City (TW)

(21) Appl. No.: 19/005,069

(22) Filed: Dec. 30, 2024

(51) Int. Cl. H10F 39/18; H01L 23/00; H01L 25/16; H10F 39/00

(52) U.S. Cl. CPC H10F 39/18; H10F 39/014; H10W 72/90; H10W 90/00

(57) ABSTRACT

A pixel sensor includes a transistor between a transfer transistor on a first semiconductor die and a source-follower gate on a second semiconductor die. The arrangement of the transistor may reduce input capacitance to the source-follower gate, which results in increased conversion gain in low-lighting conditions (e.g., high conversion gain mode) of a multiple semiconductor die image sensor device. A transistor between a first floating diffusion node coupled to the transfer transistor, and a second floating diffusion node coupled to the source-follower gate, may be turned off during signal readout from the source-follower gate, which blocks the signal path between the transistor and the transfer transistor. This prevents parasitic capacitance from the signal path from delaying and/or reducing the discharge of photocurrent from the second floating diffusion node onto the source-follower gate. As a result, substantially the full magnitude of the photocurrent can be applied to the source-follower gate.

### BACKGROUND

A complementary metal oxide semiconductor (CMOS) image sensor device may include a plurality of pixel sensors arranged in a pixel sensor array. A pixel sensor of the CMOS image sensor device may include a photodiode configured to convert photons of incident light to a photocurrent of electrons. The magnitude of the photocurrent is based at least in part on the intensity of the incident light.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram of an example of a pixel sensor described herein.

FIGS. 1B and 1C depict example timing diagrams described herein.

FIG. 2A is a diagram of an example semiconductor device described herein.

FIG. 2B is a diagram of a portion of an example semiconductor device described herein.

FIGS. 3A-3D are diagrams of an example implementation of forming a semiconductor die (or a portion thereof) described herein.

FIGS. 4A-4D are diagrams of an example implementation of forming a semiconductor die (or a portion thereof) described herein.

FIGS. 5A and 5B are diagrams of an example implementation of forming a semiconductor device (or a portion thereof) described herein.

FIG. 6A is a diagram of an example of a pixel sensor described herein.

FIG. 6B is a diagram of an example semiconductor device described herein.

FIG. 6C is a diagram of a portion of an example semiconductor device described herein.

FIG. 6D depicts example timing diagrams described herein.

FIG. 7A is a diagram of an example of a pixel sensor described herein.

FIG. 7B is a diagram of an example semiconductor device described herein.

FIG. 7C depicts example timing diagrams described herein.

FIGS. 8A-8W are diagrams of examples of pixel sensors described herein.

FIG. 9 is a flowchart of an example process associated with forming a semiconductor device described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition to a photodiode (e.g., a sensing region), a pixel sensor of an image sensor device (e.g., a complementary metal-oxide-semiconductor (CMOS) image sensor) may also include a control circuitry region. The control circuitry region is electrically connected to the photodiode and is configured to receive a photocurrent that is generated by the photodiode and to store the photocurrent in a floating diffusion node. The photocurrent in the floating diffusion node may be sampled and converted to a pixel sensor signal that can be used to generate an image and/or a video.

The control circuitry region may also include a conversion gain circuit that is configured to perform a plurality of conversion gain operations on the photocurrent to enable a high dynamic range (HDR) to be achieved for images and/or video generated by the image sensor device. Each conversion gain operation may include applying different levels of gain (e.g., a high conversion gain (HCG) operation with a high conversion gain, and a low conversion gain (LCG) operation with a low conversion gain) to the photocurrent to generate high and low pixel sensor signals that are then combined into a composite pixel sensor signal that has a high dynamic range.

The photocurrent may be used to apply a floating diffusion voltage to a source-follower gate of the control circuitry region. This permits the photocurrent to be observed without removing or discharging the photocurrent from the floating diffusion node. The source-follower gate functions as a high impedance amplifier for the pixel sensor. The source-follower gate provides a voltage-to-current conversion of the floating diffusion voltage.

In some cases, a sensing area (e.g., a photodiode) of a pixel sensor may be increased by distributing the components of the pixel sensor across multiple semiconductor dies (e.g., two or more semiconductor dies) of a three-dimensional (3D) stacked CMOS image sensor device. This enables the sensing area to be included on a different semiconductor die than other components of the pixel sensor, so that the overall size of the pixel sensor may be reduced while maintaining (or even increasing) the size of the sensing area. Accordingly, the multiple-semiconductor-die distribution of the components of the pixel sensor enables a high full well capacity (FWC) to be achieved for the pixel sensor.

However, the separation of components (e.g., transistors, capacitors, floating diffusion nodes) between semiconductor dies (e.g., from a first semiconductor die to a second semiconductor die) may induce high input capacitance to a source-follower gate due to various sources of parasitic capacitance in the signal path between a transfer gate on a first semiconductor die and a source-follower gate on a second semiconductor die. Such sources of parasitic capacitance may include the bonding connections between the first and second semiconductor dies, and/or back-end interconnect routing on the first and second semiconductor dies, among other examples.

A source-follower gate with high input capacitance may limit conversion gain in low-light modes, which may degrade performance of the pixel sensor in low light. For example, the high input capacitance may result in longer integration times for the pixel sensor. As another example, the high input capacitance may result in slower response times during signal readout from the source-follower gate, resulting in reduced conversion gain in dynamic and low-lighting conditions.

In some implementations described herein, a pixel sensor includes a transistor between a transfer transistor on a first semiconductor die and the source-follower gate on a second semiconductor die. The arrangement of the transistor between the transfer transistor and the source-follower gate may reduce input capacitance to the source-follower gate, which results in increased conversion gain in low-lighting conditions (e.g., high conversion gain mode) of a multiple semiconductor die CMOS image sensor device. In more detail, a transistor between a first floating diffusion node coupled to the transfer transistor, and a second floating diffusion node coupled to the source-follower gate, may be turned off during signal readout from the source-follower gate, which blocks the signal path between the transistor and the transfer transistor. This prevents parasitic capacitance from the signal path from delaying and/or reducing the discharge of photocurrent from the second floating diffusion node onto the source-follower gate. As a result, substantially the full magnitude of the photocurrent can be applied to the source-follower gate, as opposed to the parasitic capacitance from the signal path between the transistor and the transfer transistor causing a reduced amount of photocurrent being applied to the source-follower gate. This enables higher readout signal voltages to be achieved, thereby increasing the conversion gain. Pixel sensors including the transistor arrangement may experience reduced input capacitance to the source-follower gate, allowing for longer integration times for the pixel sensor and faster response times during signal readout from the source-follower gate, which may increase conversion gain in dynamic and low-lighting conditions in comparison to when the input capacitance is greater.

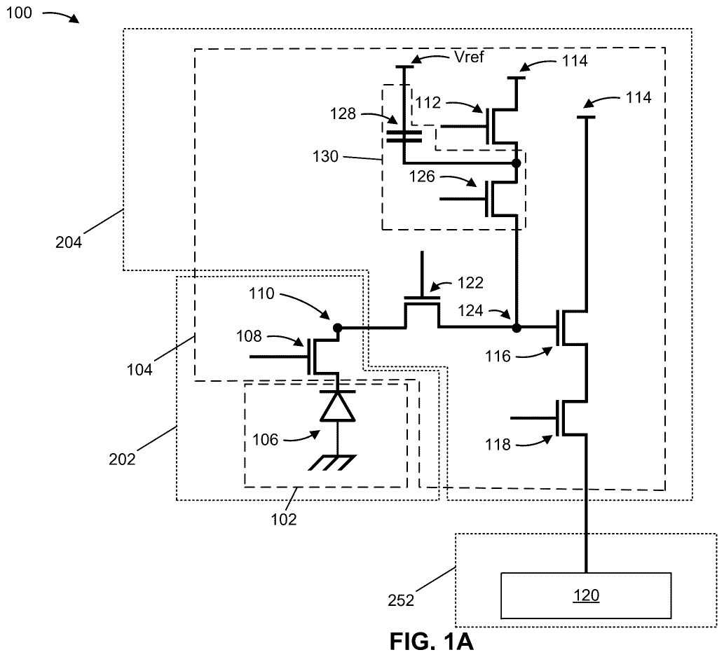

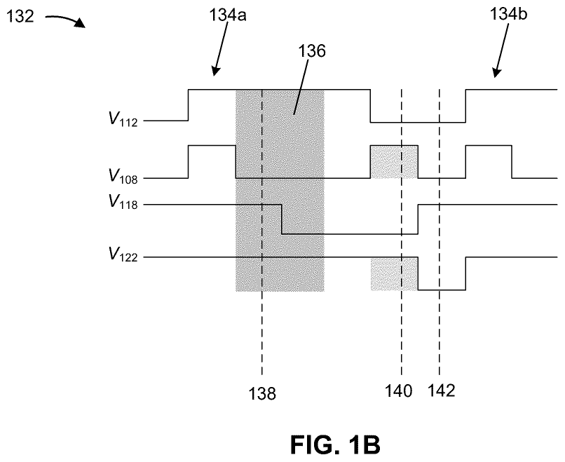

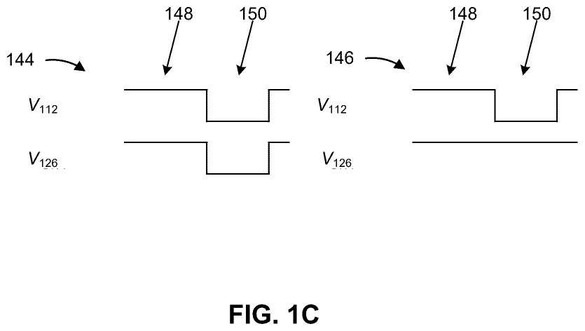

FIG. 1A is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

The pixel sensor 100 includes a sensing region 102 that may be configured to sense and/or accumulate incident light (e.g., light directed toward the pixel sensor 100). The pixel sensor 100 also includes a control circuitry region 104. The control circuitry region 104 is electrically connected with the sensing region 102 and is configured to receive a photocurrent that is generated by the sensing region 102. Moreover, the control circuitry region 104 is configured to transfer the photocurrent from the sensing region 102 to downstream circuits such as image processing circuits, among other examples.

The sensing region 102 includes a photodiode 106. The photodiode 106 may absorb and accumulate photons of the incident light, and may generate the photocurrent based on absorbed photons. The magnitude of the photocurrent is based on the amount of light collected in the photodiode 106. Thus, the accumulation of photons in the photodiode 106 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 106 is electrically connected with a source/drain of a transfer gate 108 of the control circuitry region 104. The transfer gate 108 is configured to control the transfer of the photocurrent from the photodiode 106 to a first floating diffusion node 110. The photocurrent is provided from a source/drain (e.g., which may correspond to the photodiode 106) of the transfer gate 108 to another drain/drain of the transfer gate 108 (e.g., which may correspond to the first floating diffusion node 110) based on selectively switching a gate of the transfer gate 108. The gate of the transfer gate 108 may be selectively switched by applying a transfer voltage (Vₜₓ) to the transfer gate 108. In some implementations, the transfer voltage being applied to the transfer gate 108 causes a conductive channel (e.g., a leakage path or buried channel) to form between the photodiode 106 and the first floating diffusion node 110, which enables the photocurrent to propagate through the conductive channel from the photodiode 106 to the first floating diffusion node 110. In some implementations, the transfer voltage being removed from the transfer gate 108 (or the absence of the transfer voltage) causes the conductive channel to be removed such that the photocurrent cannot pass from the photodiode 106 to the first floating diffusion node 110.

The control circuitry region 104 further includes a reset transistor 112. The reset transistor 112 is electrically connected to a supply voltage source 114. The reset transistor 112 may be controlled by a reset voltage (Vᵣₛₜ) applied by the supply voltage source 114. The control circuitry region 104 further includes a source-follower gate 116, a row-select gate 118 coupled to a source/drain of the source-follower gate 116, and an image processing circuit 120 coupled to a source/drain of the row-select gate 118.

The control circuitry region 104 also includes an intermediate transistor 122 between the first floating diffusion node and a second floating diffusion node 124. The intermediate transistor 122 may be activated or deactivated (e.g., turned on or off) to control flow of photocurrent from the transfer gate 108 and the first floating diffusion node 110 to the second floating diffusion node 124 and the source-follower gate 116. For example, the intermediate transistor 122 may be deactivated (e.g., turned off) during signal readout from the source-follower gate 116, which may block the signal path between the intermediate transistor 122 and the transfer gate 108. This prevents parasitic capacitance from the signal path from delaying and/or reducing the discharge of photocurrent from the second floating diffusion node 124 onto the source-follower gate 116. As a result, substantially the full magnitude of the photocurrent can be applied to the source-follower gate 116, as opposed to the parasitic capacitance from the signal path between the intermediate transistor 122 and the transfer gate 108 causing a reduced amount of photocurrent being applied to the source-follower gate 116. This enables higher readout signal voltages to be achieved, thereby increasing the conversion gain.

The reset transistor 112 may be electrically coupled to the second floating diffusion node 124. The reset voltage may be applied to the reset transistor 112 to pull the second floating diffusion node 124 to a high voltage (e.g., to the supply voltage) to “reset” the second floating diffusion node 124 (e.g., by draining any residual charge in the second floating diffusion node 124) prior to activation of the transfer gate 108 to transfer the photocurrent from the photodiode 106 to the second floating diffusion node 124. The intermediate transistor 122 may be activated (e.g., turned on) during activation of the transfer gate 108 to allow the transfer of the photocurrent from the photodiode 106 and the first floating diffusion node 110 through the intermediate transistor 122 to the second floating diffusion node 124.

The photocurrent may be used to apply a floating diffusion voltage (V_{fd}) to the source-follower gate 116 of the control circuitry region 104. This permits the photocurrent to be observed without removing or discharging the photocurrent from the second floating diffusion node 124. The reset transistor 112 may instead be used to remove or discharge the photocurrent from the second floating diffusion node 124.

The source-follower gate 116 functions as a high impedance amplifier for the pixel sensor 100. The source-follower gate 116 provides a voltage to current conversion of the floating diffusion voltage. The output of the source-follower gate 116 is electrically connected with the row-select gate 118, which is configured to control the flow of the photocurrent to the image processing circuit 120. The row-select gate 118 is controlled by selectively applying a select voltage (V_{di}) to the gate of the row-select gate 118. This permits the photocurrent to flow to an output of the pixel sensor 100. The image processing circuit 120 may be a part of the pixel sensor 100 or may be a separate part of a semiconductor device in which the pixel sensor 100 and the image processing circuit 120 are included.

As further shown in FIG. 1A, the control circuitry region 104 of the pixel sensor 100 includes a conversion gain circuit 130 including a conversion gain transistor 126 and a capacitor 128. The conversion gain circuit 130 can be selectively activated or deactivated to enable a conversion gain operation to be performed for an exposure operation of the pixel sensor 100 (e.g., an exposure operation to generate an image and/or a video). The conversion gain circuit 130 enables the capacitance of the pixel sensor 100 to be gradually increased through the exposure operation, which gradually increases the full-well capacity (FWC) of the pixel sensor 100. The increased capacitance enables additional charge to be stored in the control circuitry region 104 during the exposure operation, which enables the level of the photocurrent to be increased during the exposure operation. In this way, the conversion gain can be inversely decreased so that a high dynamic range can be achieved in the exposure operation.

The conversion gain circuit 130 includes the conversion gain transistor 126 and the capacitor 128. A first source/drain terminal of the conversion gain transistor 126 is electrically coupled to the second floating diffusion node 124, and a second source/drain terminal of the conversion gain transistor 126 is electrically coupled to the capacitor 128. The capacitor 128 is electrically coupled to a reference voltage source (Vref). The capacitor 128 is electrically coupled to the second floating diffusion node 124 through the conversion gain transistor 126.

In some implementations, Vref may be the same as the supply voltage source 114. In some implementations, Vref may be different than the supply voltage source 114.

The conversion gain transistor 126 enables the conversion gain circuit 130 to be selectively activated or deactivated, respectively. For example, when the conversion gain transistor 126 is activated, the capacitor 128 may be connected to the second floating diffusion node 124, thereby enabling the capacitor 128 to function as a lateral overflow integration capacitor (LOFIC) for the second floating diffusion node 124. In particular, the capacitor 128 may store overflow charge from the second floating diffusion node 124, thereby enabling additional charge generated by the photodiode 106 to be stored in the second floating diffusion node 124 without the second floating diffusion node 124 reaching saturation. When the conversion gain transistor 126 is deactivated, the capacitor 128 may be disconnected from the second floating diffusion node 124.

The capacitor 128 and the reset transistor 112 may be electrically coupled to the second source/drain terminal of the conversion gain transistor 126 and to the supply voltage source 114 in parallel. The second floating diffusion node 124 may be reset by activating the conversion gain transistor 126 and the reset transistor 112.

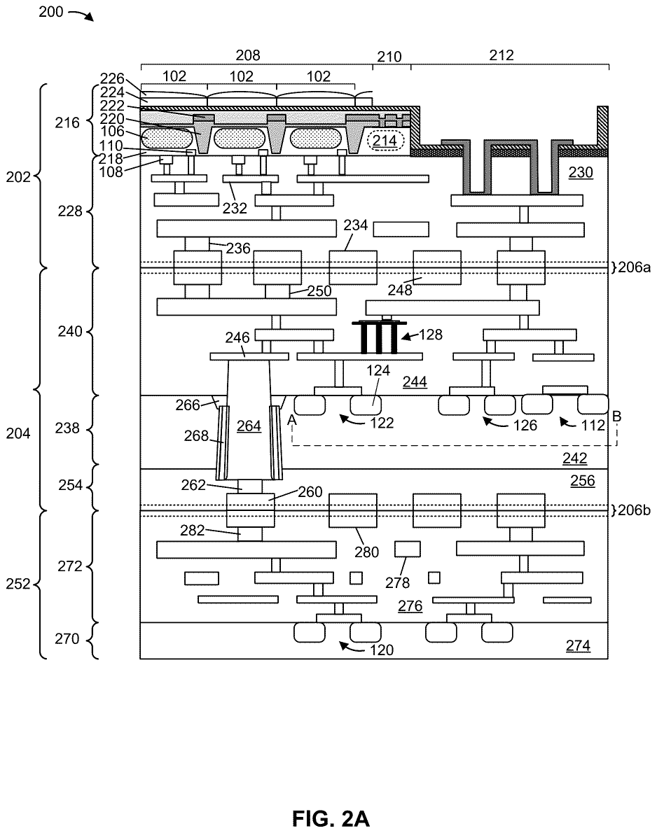

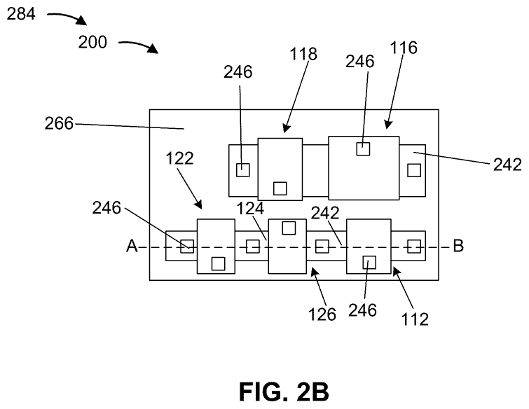

As shown in FIG. 1A, and explained in more detail in connection FIG. 2A, the sensing region 102 of the pixel sensor 100 may be included on a semiconductor die 202 (e.g., an image sensor die). Moreover, a portion of the control circuitry region 104 of the pixel sensor 100, including the transfer gate 108 and the first floating diffusion node 110, may be included on the semiconductor die 202. Another portion of the control circuitry region 104 of the pixel sensor 100 may be included on a semiconductor die 204. Thus, the control circuitry region 104 of the pixel sensor is distributed across a plurality of semiconductor dies. The reset transistor 112, the source-follower gate 116, the row-select gate 118, the intermediate transistor 122, the second floating diffusion node 124, and the conversion gain circuit 130 (including the conversion gain transistor 126 and the capacitor 128) may be included on the semiconductor die 204. The semiconductor die 204 may be an application-specific integrated circuit (ASIC) die. The image processing circuit 120 may be included on a semiconductor die 252 (e.g., an image sensor processing (ISP) die).

FIG. 1B depicts an example timing diagram 132 corresponding to the operation of the pixel sensor 100. The timing diagram 132 includes a first reset period 134a, a second reset period 134b, an integration time period 136, a reference level period 138, a photocurrent transfer period 140, and a signal readout period 142. The designations V₁₁₂, V₁₀₈, V₁₁₈, and V₁₂₂ correspond to high or low voltage levels being applied to the gate of the reset transistor 112, the transfer gate 108, the row-select gate 118, and the gate of the intermediate transistor 122 to respectively activate or deactivate the corresponding transistors. The first reset period 134a and the second reset period 134b correspond to when a reset voltage may be applied to the reset transistor 112 to pull the second floating diffusion node 124 to a high voltage (e.g., to the supply voltage) to “reset” the second floating diffusion node 124 (e.g., by draining any residual charge in the second floating diffusion node 124). As can be seen, the transfer gate 108 and the reset transistor 112 are activated during the first reset period 134a and the second reset period 134b. With the exception of the photocurrent transfer period 140 and the signal readout period 142, the reset transistor 112 remains activated.

The integration time period 136 corresponds to the time period of an exposure operation to generate an image and/or a video. In other words, the integration time period 136 corresponds to a time period during which the photodiode 106 is collecting photons to generate an image and/or a video. The transfer gate 108 is deactivated during the integration time period 136. The reference level period 138 corresponds to a time period during which a reference (e.g., baseline) voltage level is established. The reference level period 138 occurs at a beginning of the integration time period 136. The row-select gate 118 is activated during the reference level period, and deactivated until the signal readout period 142.

The photocurrent transfer period 140 corresponds to the time period during which the transfer gate 108 is activated to transfer the photocurrent from the photodiode 106 to the first floating diffusion node 110, the intermediate transistor 122, and to the second floating diffusion node 124. In order to enable the transfer, the intermediate transistor 122 is activated during the photocurrent transfer period 140 to allow the photocurrent to flow from the transfer gate 108 to the second floating diffusion node 124.

The signal readout period 142 corresponds to the time period during signal readout from the source-follower gate 116. The reset transistor 112, the transfer gate 108, and the intermediate transistor 122 are deactivated during the signal readout period 142, while the row-select gate 118 is activated during the signal readout period 142. The intermediate transistor 122 may be deactivated (e.g., turned off) during the signal readout period 142 to block the signal path between the intermediate transistor 122 and the transfer gate 108, which prevents parasitic capacitance from the signal path from delaying and/or reducing the discharge of photocurrent from the second floating diffusion node 124 onto the source-follower gate 116.

FIG. 1C depicts an example timing diagram 144 corresponding to a first conversion gain operation (e.g., an HCG operation) in the pixel sensor 100, and an example timing diagram 146 corresponding to a second conversion gain operation (e.g., an LCG operation) in the pixel sensor 100. The timing diagrams 144 and 146 each include reset periods 148 and read periods 150. The designations V₁₁₂ and V₁₂₆ correspond to high or low voltage levels being applied to the gate of the reset transistor 112, and to the gate of the conversion gain transistor 126 to respectively activate or deactivate the corresponding transistors. During the first conversion gain operation, the reset transistor 112 and the conversion gain transistor 126 are deactivated during the read period 150. During the second conversion gain operation, the reset transistor 112 is deactivated and the conversion gain transistor 126 is activated during the read period 150.

As indicated above, FIGS. 1A-1C are provided as examples. Other examples may differ from what is described with regard to FIGS. 1A-1C.

FIG. 2A is a diagram of an example semiconductor device 200 described herein. The semiconductor device 200 includes an image sensor device such as a CMOS image sensor device that includes one or more pixel sensors 100. FIG. 2A illustrates a cross-sectional view of a structural implementation of the semiconductor device 200.

As shown in FIG. 2A, the semiconductor dies 202, 204, and 252 may be vertically stacked or vertically arranged in the semiconductor device 200. The semiconductor die 202 and the semiconductor die 204 may be bonded at a bonding interface 206a, and the semiconductor die 204 and the semiconductor die 252 may be bonded at a bonding interface 206b. Thus, the semiconductor device 200 may be a three-dimensional (3D) CMOS image sensor (3D CIS) because of the vertical arrangement of the semiconductor dies 202, 204, 252. The bond between the semiconductor dies 202, 204, and 252 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 202, 204, and 252 by forming metal-to-metal bonds and/or dielectric-to-dielectric bonds at the bonding interfaces 206 between the semiconductor dies 202 and 204, and at the bonding interface 206b between the semiconductor dies 204 and 252.

The semiconductor die 202 may include a pixel sensor array 208, a black level correction (BLC) region 210 adjacent to (e.g., horizontally adjacent to) the pixel sensor array 208, and a bonding pad region 212 adjacent to (e.g., horizontally adjacent to) the BLC region 210, among other examples. In some implementations, the semiconductor die 202 includes additional lateral regions, such as a seal ring region and/or a scribe line region, among other examples.

The pixel sensor array 208 includes a plurality of sensing regions 102 of a plurality of pixel sensors 100. The sensing regions 102 of the pixel sensors 100 may be arranged in a grid or in another type of arrangement, and may be configured to generate photocurrents based on photons of incident light. The BLC region 210 may include a region 214 in a device layer 216 of the semiconductor die 202 that is shielded from incident light by a metal shielding layer. The metal shielding layer may be included as a light-blocking layer to prevent incident light from entering the region 214. The region 214 is thus a sensing region that is kept “dark” so that dark current measurements may be performed in the BLC region 210. A dark current measurement may be performed to measure the amount of charge (dark current) in the device layer 216 that is generated from sources other than incident light (e.g., from thermal energy in the device layer 216) so that the dark current measurement may be used for black level correction (or black level calibration) for the pixel sensor array 208. The bonding pad region 212 may include a bonding pad structure that enables an external electrical connection to be formed with the semiconductor device 200.

The device layer 216 includes a substrate layer 218. The substrate layer 218 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material.

Photodiodes 106 of the sensing regions 102 of the pixel sensors 100 are included in the substrate layer 218 of the semiconductor die 202. The photodiodes 106 may each include one or more doped regions of substrate layer 218. The substrate layer 218 may be doped with a plurality of types of ions to form a p-n junction or a PIN junction (e.g., a junction between a p-type portion, an intrinsic (or undoped) type portion, and an n-type portion) corresponding to a photodiode 106. For example, the substrate layer 218 may be doped with an n-type dopant to form a first portion (e.g., an n-type portion) of a photodiode 106 and a p-type dopant to form a second portion (e.g., a p-type portion) of the photodiode 106. A photodiode 106 may be configured to absorb photons of incident light. The absorption of photons causes the photodiode 106 to accumulate a charge (a photocurrent) due to the photoelectric effect. Here, photons bombard the photodiode 106, which causes emission of electrons of the photodiode 106. The emission of electrons causes the formation of electron-hole pairs, where the electrons migrate toward the cathode of the photodiode 106 and the holes migrate toward the anode, which produces the photocurrent.

The photodiodes 106 may be electrically isolated and/or optically isolated from one another by one or more isolation structures in the substrate layer 218. For example, a deep trench isolation (DTI) structure 220 may extend into the substrate layer 218 from a back side of the substrate layer 218. The DTI structure 220 may include elongated structures that include one or more dielectric layers, one or more metal layers, and/or another arrangement of layers and/or materials. The DTI structure 220 may laterally surround the photodiodes 106 of the pixel sensors 100 in the substrate layer 218.

A grid structure 222 may be included above the back side of the substrate layer 218. Sections of the grid structure 222 may be located over the DTI structure 220 and may be formed around the perimeter of the photodiodes 106 of the sensing regions 102 of the pixel sensors 100. Openings in the grid structure 222 are included above the photodiodes 106 to enable incident light to pass through the grid structure 222 and to the photodiodes 106. In some implementations, the grid structure 222 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples. In some implementations, the grid structure 222 may be formed of a dielectric material. In some implementations, the grid structure 222 is a multi-layer structure that includes one or more metal layers and/or one or more dielectric layers that are vertically stacked.

Color filter regions 224 of the sensing regions 102 of the pixel sensors 100 may be included in the openings in the grid structure 222. The color filter regions 224 may be included above the photodiodes 106 of the sensing regions 102 of the pixel sensors 100. The color filter regions 224 may be included above the photodiodes 106. Each color filter region 224 may be configured to filter incident light to allow a particular wavelength of the incident light to pass to a photodiode 106. For example, a color filter region 224 may filter incident light to allow red light to pass through the color filter region 224 to an associated photodiode 106. As another example, a color filter region 224 may filter incident light to allow green light to pass through the color filter region 224 to an associated photodiode 106. As another example, a color filter region 224 may filter incident light to allow blue light to pass through the color filter region 224 to an associated photodiode 106. In some implementations, a color filter region 224 may be non-discriminating or non-filtering, which may define a white pixel sensor. A non-discriminating or non-filtering color filter region 224 may include a material that permits all wavelengths of light to pass into the associated photodiode 106 (e.g., for purposes of determining overall brightness to increase light sensitivity for the image sensor). In some implementations, a color filter region 224 may be a near infrared (NIR) bandpass color filter region 224, which may define an NIR pixel sensor. An NIR bandpass color filter region 224 may include a material that permits the portion of incident light in an NIR wavelength range to pass to an associated photodiode 106 while blocking visible light from passing.

Micro-lenses 226 may be included over and/or on the color filter regions 224. The micro-lenses 226 may include a respective micro-lens for each of the sensing regions 102 of the pixel sensors 100. A micro-lens 226 may be formed to focus incident light toward a photodiode 106 of a sensing region 102 of a pixel sensor 100.

Transfer gates 108 of the pixel sensors 100 are included on the front side of the substrate layer 218. The transfer gates 108 are configured to selectively control the flow of photocurrents from the photodiodes 106 to first floating diffusion nodes 110 of the pixel sensors 100. The first floating diffusion nodes 110 may also be included in the substrate layer 218. A transfer gate 108 may selectively control the flow of a photocurrent from a photodiode 106 of a pixel sensor 100 to a first floating diffusion node 110 of the pixel sensor 100 by selectively controlling a leakage path (e.g., a buried channel) between the photodiode 106 and the first floating diffusion node 110 in the substrate layer 218. When a gate voltage (e.g., a transfer voltage (Vₜₓ)) is applied to the transfer gate 108, the leakage path may be formed in the substrate layer 218, thereby enabling a photocurrent to flow from the photodiode 106 to the first floating diffusion node 110. When the gate voltage is removed, the leakage path is closed, thereby preventing the photocurrent from floating from the photodiode 106 to the first floating diffusion node 110.

Not shown in FIG. 2A are additional components of the control circuitry regions 104 of the pixel sensors 100 that may be included in the substrate layer 218. Such components may include, for example, the source-follower gates 116, and/or the row-select gates 118, among other examples.

The semiconductor die 202 may include an interconnect layer 228 vertically adjacent to the device layer 216. The interconnect layer 228 may include a dielectric region 230 that includes one or more dielectric layers. The dielectric layers may include backend dielectric layers (e.g., interlayer dielectric (ILD) layers, intermetal dielectric (IMD) layers) and etch stop layers (ESLs)) that are arranged in a direction that is approximately orthogonal to the substrate layer 218. The dielectric regions 230 may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 228 may further include a plurality of conductive structures 232 (e.g., electrically conductive structures) in the dielectric region 230. The conductive structures 232 are electrically coupled and/or physically coupled to the transfer gates 108, the first floating diffusion nodes 110, and/or other structures of the pixel sensors 100 in the device layer 216. Moreover, the conductive structures 232 may be electrically interconnected together in the interconnect layer 228. The conductive structures 232 correspond to circuit routing that enables signals and/or power to be provided to and/or from components of the pixel sensors 100 in the device layer 216. The conductive structures 232 may include a combination of conductive structures that extend primarily horizontally in the interconnect layer 228 (e.g., trenches, conductive lines) and that are interconnected by interconnect structures (e.g., vias) that extend primarily vertically in the interconnect layer 228. The conductive structures 232 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 228 may be arranged in a vertical manner to facilitate electrical signals and/or power to be routed between the device layer 216 and the semiconductor die 204, between integrated circuit devices in the device layer 216 through the interconnect layer 228, and/or between the integrated circuit devices in the device layer 216 and integrated circuit devices in the semiconductor die 204. The conductive structures 232 may be arranged in alternating layers of metallization layers (referred to as “M”-layers) and via layers (referred to as “V”-layers). Each metallization layer may include one or more conductive structures laterally arranged in the interconnect layer 228, and each via layer may include one or more interconnect structures that interconnect the metallization layers in the interconnect layer 228. As an example, a metal-0 (M0) layer may be located at the bottom of the interconnect layer 228 and may be coupled to the integrated circuit devices (e.g., the transfer gates 108, the first floating diffusion nodes 110) in the device layer 216, a via-0 (V0) layer may be located above and coupled to the M0 layer in the interconnect layer 228, a metal-1 (M1) layer may be located above and coupled to the V0 layer in the interconnect layer 228, a via-1 (V1) layer may be located above and coupled to the M1 layer in the interconnect layer 228, a metal-2 (M2) layer may be located above and electrically coupled to the V1 layer in the interconnect layer 228, and so on. In some implementations, the interconnect layer 228 includes nine (9) stacked metallization layers (e.g., M0-M8). In other implementations, the contact layer (referred to as “CO”-layer) may be located at the bottom of the interconnect layer 228 and may be directly coupled to the integrated circuit devices (e.g., with the transfer gates 108, with the floating diffusion nodes 110) in the device layer 216, a metal-1 (M1) layer may be located above and coupled to the CO layer in the interconnect layer 228, and so on. In some implementations, the interconnect layer 228 includes another quantity of stacked metallization layers.

At the bonding interface 206a between the semiconductor dies 202 and 204, the interconnect layer 228 may include a plurality of bonding pads 234. The bonding pads 234 may be electrically coupled to the conductive structures 232 in the interconnect layer 228 by bonding vias 236 and/or other types of conductive structures. The bonding pads 234 and the bonding vias 236 may each include tungsten (W), cobalt (Co), ruthenium (Ru), titanium (Ti), aluminum (Al), copper (Cu), gold (Au), and/or a combination thereof, among other examples of electrically conductive metals.

The semiconductor die 204 may include one or more components of the image processing circuits 120 coupled to the pixel sensors 100 of the semiconductor device 200. The semiconductor die 204 may include a device layer 238 and an interconnect layer 240 vertically adjacent to the device layer 238. The device layer 238 may include a substrate layer 242, and one or more components of the image processing circuits 120 may be included in and/or on the substrate layer 242. The substrate layer 242 may include a silicon (Si) substrate, an SOI substrate, and/or another type of substrate. The image processing circuits 120 may include integrated circuit devices such as transistor structures (e.g., planar transistors, fin field effect transistors (finFETs), nanostructure transistors (e.g., nanosheet transistors, gate all around (GAA) transistors), capacitor structures, resistor structures, inductor structures, and/or other types of semiconductor structures).

The interconnect layer 240 may include a similar combination and/or arrangement of structures and/or layers as the interconnect layer 228 of the semiconductor die 202. For example, the interconnect layer 240 may include a dielectric region 244 (similar to the dielectric region 230) and a combination of conductive structures 246 (similar to the conductive structures 232) in the dielectric region 244. Moreover, the interconnect layer 240 may include bonding pads 248 that are electrically coupled to one or more of the conductive structures 246 by bonding vias 250. These layers and/or structures may have a reversed vertical arrangement relative to the semiconductor die 202, which enables the semiconductor die 202 and the semiconductor die 204 to be bonded at the bonding interface 206 such that the interconnect layer 228 and the interconnect layer 240 are facing each other and bonded together.

At the bonding interface 206a, the bonding pads 234 of the semiconductor die 204 and bonding pads 248 of the semiconductor die 204 are directly bonded by metal-to-metal bonds. Moreover, the dielectric region 230 of the semiconductor die 202 and the dielectric region 244 of the semiconductor die 204 are directly bonded by dielectric-to-dielectric bonds.

As further shown in FIG. 2A, the semiconductor die 204 may include another interconnect layer 254. The interconnect layer 254 may be located on a second side (e.g., a back side) of the substrate layer 242 such that the interconnect layers 240 and 254 are located on vertically opposing sides of the substrate layer 242 of the semiconductor die 204. The interconnect layer 254 may be configured to route signals and/or power between the semiconductor dies 204 and 252. The interconnect layer 254 may include a similar combination and/or arrangement of structures and/or layers as the interconnect layer 240 of the semiconductor die 204. For example, the interconnect layer 254 may include a dielectric region 256 (similar to the dielectric region 244), bonding pads 260 and one or more bonding vias 262. The bonding pads 260 enable the semiconductor die 204 to be bonded to the semiconductor die 252 at the bonding interface 206b.

One or more elongated conductive structures 264 may be included in the semiconductor die 204. An elongated conductive structure 264 may extend between the interconnect layers 240 and 254 through the substrate layer 242 of the device layer 238. An elongated conductive structure 264 may include a through substrate via (TSV), a metal pillar, a metal column, and/or another type of vertically elongated conductive structure that physically connects and electrically connects with a conductive structure 246 (e.g., a metal pad) in the interconnect layer 240 at a first end, and that physically connects and electrically connects with a bonding via 262 in the interconnect layer 254. An elongated conductive structure 264 may be referred to as a TSV structure in that the elongated conductive structure 264 extends fully through the substrate layer 242 (e.g., a semiconductor substrate such as a silicon substrate) of the device layer 238, as opposed to extending fully through a dielectric layer or an insulator layer. An elongated conductive structure 264 may further extend through a shallow trench isolation (STI) region 266 that is included in the substrate layer 242 of the device layer 238.

An elongated conductive structure 264 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. An STI region 266 may include one or more dielectric materials such as a silicon oxide material (SiOₓ such as SiO₂), a silicon nitride material (SiₓN_{y} such Si₃N₄), and/or another suitable dielectric material.

One or more liners 268 may be included between the sidewalls of the elongated conductive structure 264 and the substrate layer 242. The one or more liners 268 may include adhesion liners, barrier liners, diffusion liners, and/or another type of liners. In some implementations, a liner 268 includes a high-k dielectric liner that includes a high-k dielectric material having a dielectric constant that is greater than approximately 3.9. Examples of such materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a—LaAlOₓ such as a—LaAlO₃), among other examples. In some implementations, a liner 268 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 2A, the capacitor 128 of the conversion gain circuit 130 may be included in the interconnect layer 240 of the semiconductor die 204. In other words, the capacitor 128 may be included on the front side of the semiconductor die 204. The reset transistor 112, the source-follower gate 116, the row-select gate 118, the intermediate transistor 122, the second floating diffusion node 124, and/or the conversion gain transistor 126 may be included in and/or on the substrate layer 242 of the semiconductor die 204. In some implementations, the reset transistor 112, the source-follower gate 116, the row-select gate 118, the intermediate transistor 122, the second floating diffusion node 124, and/or the conversion gain transistor 126 may be included in and/or on a front side of the substrate layer 242 facing the interconnect layer 240. In some implementations, the reset transistor 112, the source-follower gate 116, the row-select gate 118, the intermediate transistor 122, the second floating diffusion node 124, and/or the conversion gain transistor 126 may be included in and/or on a back side of the substrate layer 242 facing the interconnect layer 254.

Additionally and/or alternatively, one or more of the capacitors 128 may be included in the device layer 216 (e.g., in the substrate layer 218) of the semiconductor die 202. The capacitors 128 may be electrically coupled to the second floating diffusion nodes 124 of the pixel sensors 100 through one or more conductive structures 246 in the interconnect layer 240. The capacitors 128 may be implemented as various types of capacitor structures, such as planar capacitor structures, trench capacitor structures, deep trench capacitor (DTC) structures, and/or other types of capacitor structures. In some implementations, a source/drain region (or source/drain terminal) of the intermediate transistor 122 may include the second floating diffusion node 124. In other implementations, the second floating diffusion node 124 may be a separate region from the source/drain region (or source/drain terminal) of the intermediate transistor 122.

The semiconductor die 252 may include a device layer 270 and an interconnect layer 272 vertically adjacent to the device layer 270. The device layer 270 may include a substrate layer 274. The substrate layer 274 may include a silicon (Si) substrate and/or another type of semiconductor substrate. The integrated circuit devices of the image processing circuits 120 may be included in and/or on the substrate layer 274. The image processing circuits 120 of the semiconductor die 252 may be configured to perform functions such as compression, storage, file management, and/or other functions associated with images and/or video generated by the semiconductor device 200. The integrated circuit devices of the image processing circuits 120 may include transistors, capacitors, resistors, and/or other integrated circuit devices.

The interconnect layer 272 may be located vertically adjacent to the front side of the substrate layer 274. The interconnect layer 272 may include a similar combination and/or arrangement of structures and/or layers as the interconnect layer 240 of the semiconductor die 204. For example, the interconnect layer 272 may include a dielectric region 276 (similar to the dielectric region 244) and a combination of conductive structures 278 (similar to the conductive structures 246) in the dielectric region 276. Moreover, the interconnect layer 272 may include bonding pads 280 that are electrically coupled to one or more of the conductive structures 278 through bonding vias 282. These layers and/or structures may have a reversed vertical arrangement relative to the interconnect layer 254, which enables the semiconductor die 204 and the semiconductor die 252 to be bonded at the bonding interface 206b such that the interconnect layer 254 and the interconnect layer 272 are facing each other and bonded together.

At the bonding interface 206b, the bonding pads 260 of the semiconductor die 204 and bonding pads 280 of the semiconductor die 252 are directly bonded by metal-to-metal bonds. Moreover, the dielectric region 256 of the semiconductor die 204 and the dielectric region 276 of the semiconductor die 252 are directly bonded by dielectric-to-dielectric bonds.

FIG. 2B is a diagram of an example implementation 284 of a portion of the semiconductor device 200 described herein. In the example implementation 284, FIG. 2B is a top view of a portion of the semiconductor device 200 including the reset transistor 112, the source-follower gate 116, the row-select gate 118, the intermediate transistor 122, the second floating diffusion node 124, and the conversion gain transistor 126. The substrate layer 242 includes source/drain regions corresponding to adjacent gates of a given transistor. A source/drain region of the intermediate transistor 122 includes the second floating diffusion node 124. The conductive structures 246 contacting the gates and source/drain regions respectively correspond to source/drain interconnects and/or gate interconnects. An STI region 266 is formed around the reset transistor 112, the source-follower gate 116, the row-select gate 118, the intermediate transistor 122, the second floating diffusion node 124, and the conversion gain transistor 126. A cross-section taken along the line A-B in FIG. 2B is illustrated by the portion of FIG. 2A including the intermediate transistor 122, the second floating diffusion node 124, the conversion gain transistor 126, and the reset transistor 112 in the substrate layer 242.

As indicated above, FIGS. 2A and 2B are provided as an example. Other examples may differ from what is described with regard to FIGS. 2A and 2B.

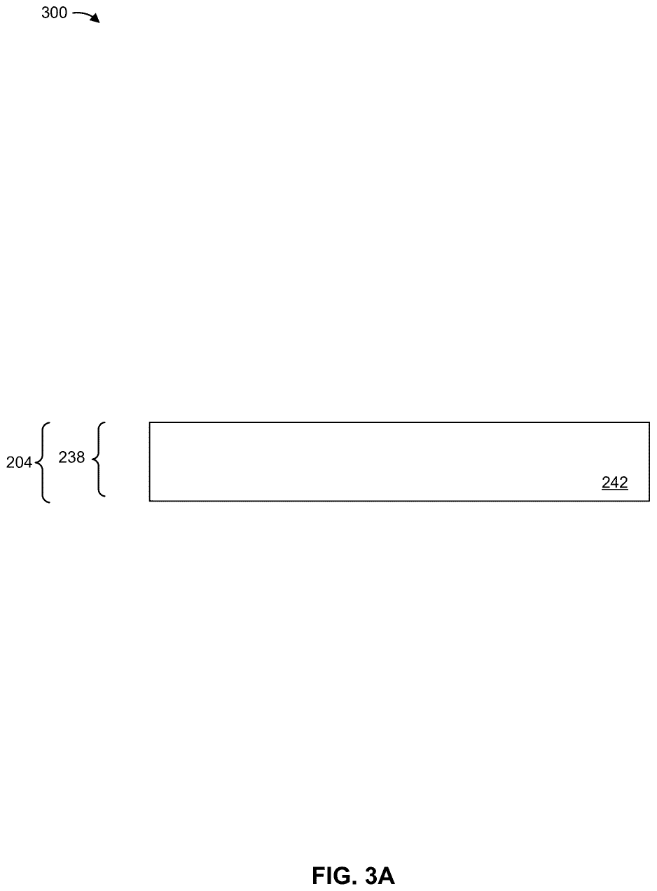

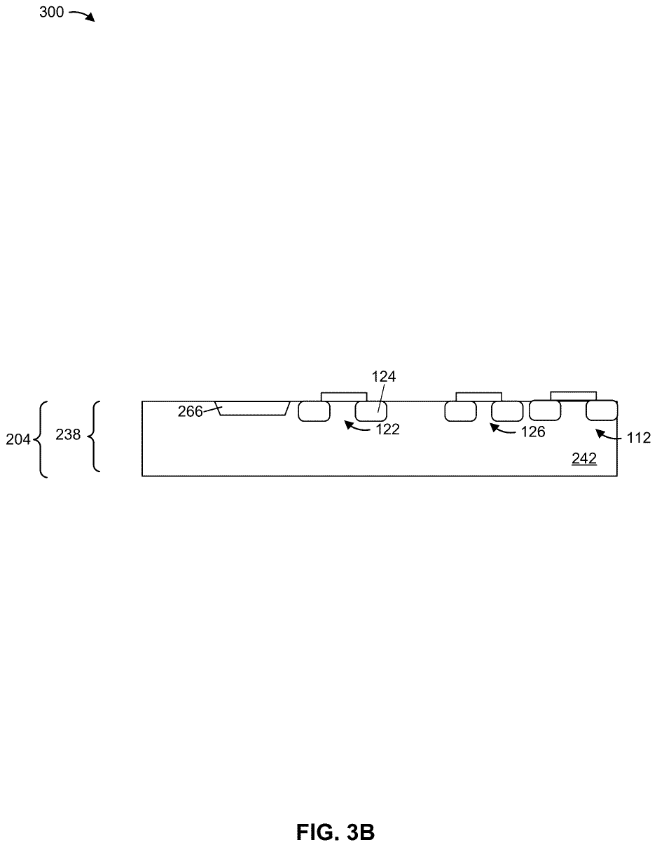

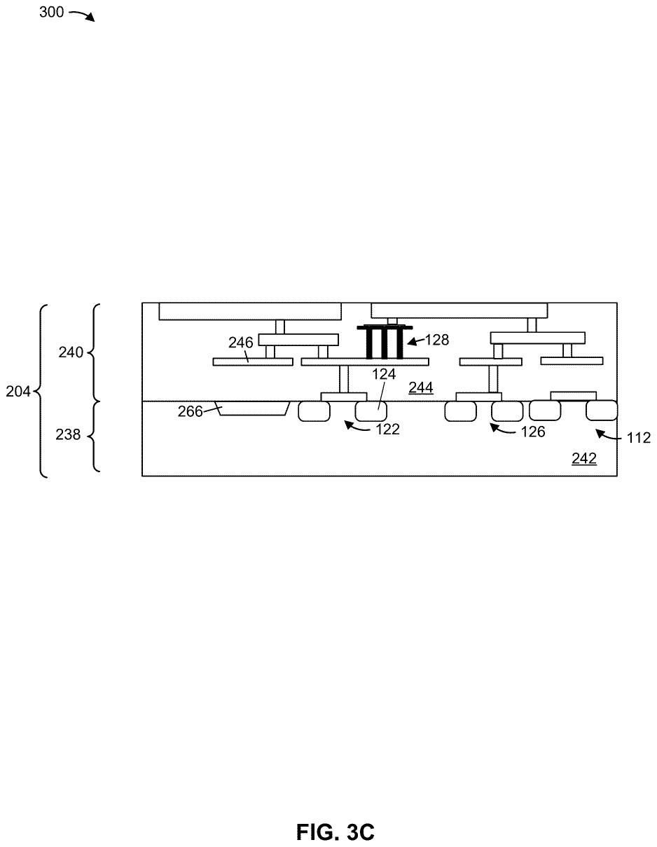

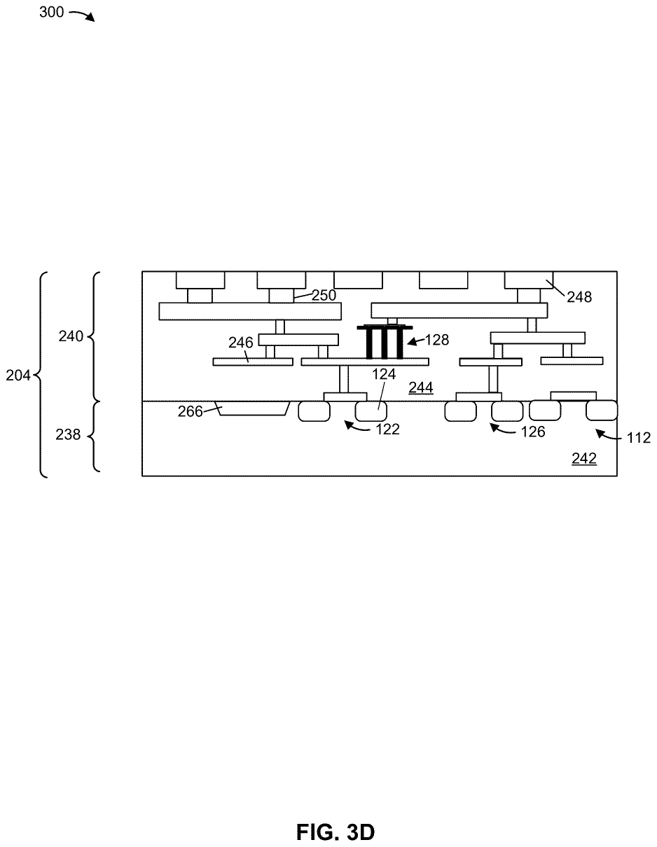

FIGS. 3A-3D are diagrams of an example implementation 300 of forming the semiconductor die 204 (or a portion thereof) of the semiconductor device 200 described herein. In some implementations, the example implementation 300 includes an example front side process for the semiconductor die 204. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 300 may be performed in connection with the substrate layer 242 of the device layer 238 of the semiconductor die 204. The substrate layer 242 may be provided in the form of a semiconductor wafer (e.g., a silicon wafer), an SOI wafer, or another type of semiconductor substrate.

As shown in FIG. 3B, the integrated circuit devices may be formed in and/or on the front side of the substrate layer 242 of the semiconductor die 204. For example, one or more of the reset transistor 112, the source-follower gate 116 (not shown), the row-select gate 118 (not shown), the intermediate transistor 122, the second floating diffusion node 124, the conversion gain transistor 126, and/or the capacitor 128 (not shown may be formed in and/or on the front side of the substrate layer 242.

One or more semiconductor processing tools may be used to form one or more portions of the integrated circuit devices. For example, a deposition tool may be used to perform various deposition operations to deposit layers of the integrated circuit devices, and/or to deposit photoresist layers for etching the substrate layer 242 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 242 and/or portions of the deposited layers to form the integrated circuit devices. As another example, a planarization tool may be used to planarize portions of the integrated circuit devices. As another example, an ion implantation tool may be used to implant ions in the substrate layer 242 to dope portions of the substrate layer 242 with one or more types of dopants (e.g., p-type dopants, n-type dopants).

As further shown in FIG. 3B, an STI region 266 may be formed in the front side of the substrate layer 242. The STI region 266 may be formed in a recess in the substrate layer 242. In some implementations, a pattern in a photoresist layer is used to etch the substrate layer 242 to form the recess in the substrate layer 242. In these implementations, a deposition tool may be used to form the photoresist layer on the substrate layer 242. An exposure tool may be used to expose the photoresist layer to a radiation source to pattern the photoresist layer. A developer tool may be used to develop and remove portions of the photoresist layer to expose the pattern. An etch tool may be used to etch the substrate layer 242 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 242 based on a pattern.

A deposition tool may be used to deposit the dielectric material of the STI region 266 in the recess using a chemical vapor deposition (CVD) technique, an atomic layer deposition (ALD) technique, a physical vapor deposition (PVD) technique, an oxidation technique, and/or another suitable deposition technique. The dielectric material of the STI region 266 may be deposited in one or more deposition operations. In some implementations, a planarization tool may be used to perform a planarization operation (e.g., a chemical mechanical planarization (CMP) operation) to planarize the STI region 266 after the dielectric material of the STI region 266 is deposited.

As shown in FIG. 3C, the interconnect layer 240 of the semiconductor die 204 may be formed above the front side of the substrate layer 242 of the semiconductor die 204. One or more semiconductor processing tools may be used to form the interconnect layer 240 by forming one or more dielectric layers of the dielectric region 244 of the interconnect layer 240 and forming a plurality of conductive structures 246 in the dielectric layer(s) of the dielectric region 244. For example, a deposition tool may be used to deposit a first dielectric layer of the dielectric region 244 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 246 in the recesses (e.g., using a CVD technique, an ALD technique, a PVD technique, an electroplating technique, and/or another type of deposition technique). At least a portion of the first layer of conductive structures 246 may be electrically connected and/or physically connected with the integrated circuit devices in the substrate layer 242 (e.g., directly connected or connected through contacts). Similar processing operations may be performed to form additional layers of the interconnect layer 240 until a sufficient or desired arrangement of conductive structures 246 is achieved.

As further shown in FIG. 3C, one or more capacitor structures, such as one or more capacitors 128, may be formed above the front side of the substrate layer 242 in the interconnect layer 240. In some implementations, a capacitor 128 is formed by depositing a metal-insulator-metal (MIM) layer stack, and etching the MIM layer stack to define a planar capacitor structure. In some implementations, in these examples, a capacitor 128 is formed by forming a trench in the dielectric region 244 and forming the MIM layer stack in the trench to define a trench capacitor structure or DTC structure. Additionally and/or alternatively, one or more of the capacitors 128 may be formed in the substrate layer 242.

As shown in FIG. 3D, the bonding vias 250 may be formed on one or more conductive structures 246 in the interconnect layer 240, and bonding pads 248 may be formed above and/or on the bonding vias 250.

As indicated above, FIGS. 3A-3D are provided as an example. Other examples may differ from what is described with regard to FIGS. 3A-3D.

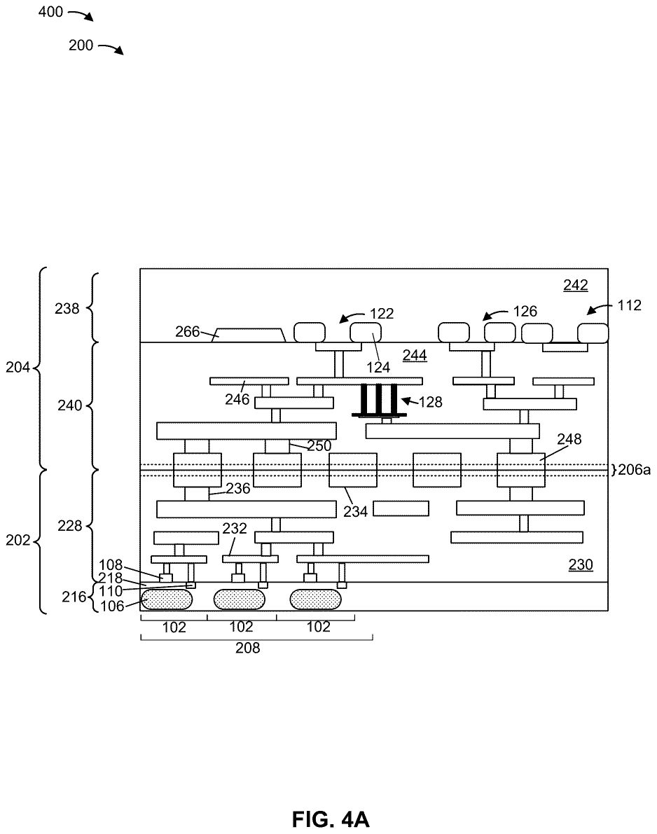

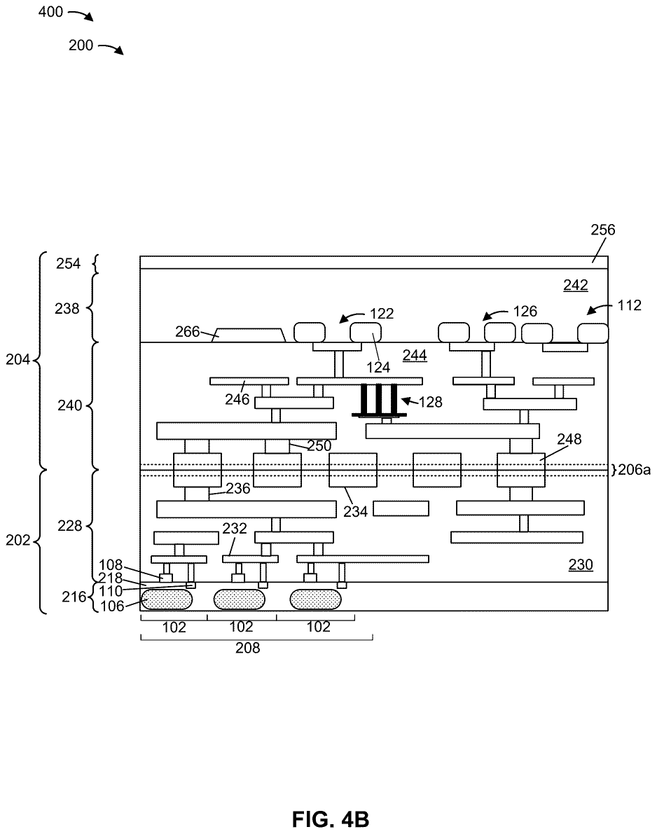

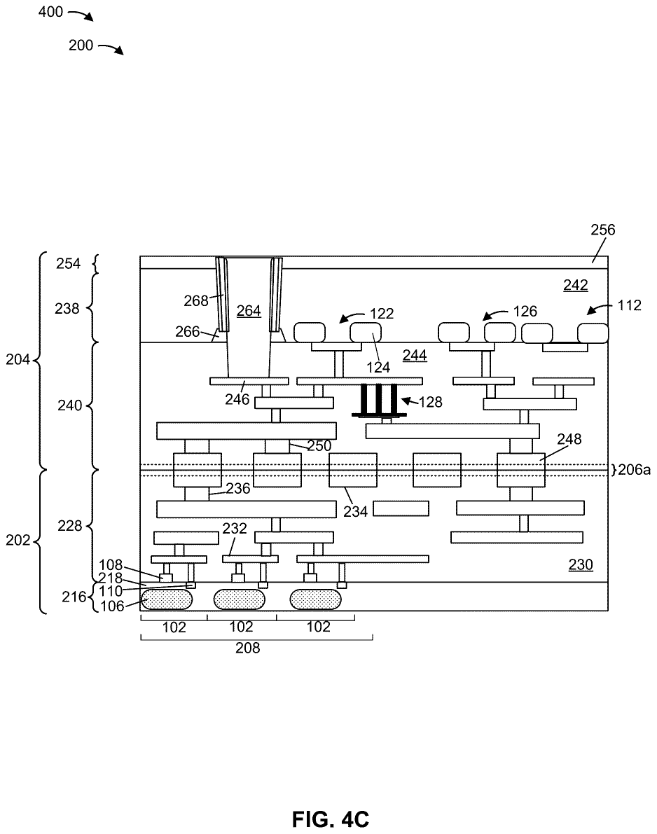

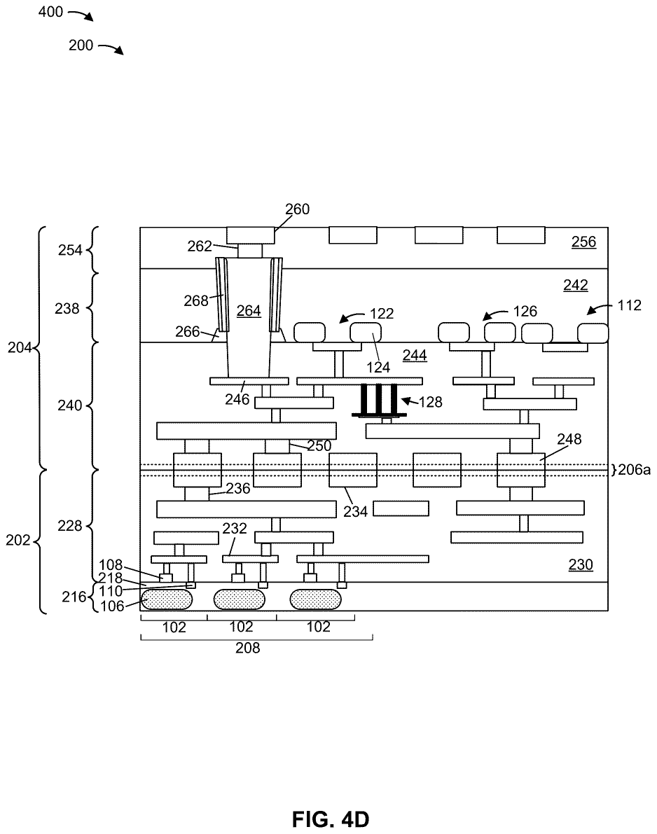

FIGS. 4A-4D are diagrams of an example implementation 400 of forming the semiconductor device 200 (or a portion thereof) described herein. For example, the example implementation 400 may include an example of bonding the semiconductor dies 202 and 204 of the semiconductor device 200, and performing back side processing on the semiconductor die 204 after bonding. In some implementations, one or more semiconductor processing tools may be used to perform one or more of the operations described in connection with the example implementation 400, such as a deposition tool, an exposure tool, a developer tool, an etch tool, a planarization tool, a bonding tool, and/or another type of semiconductor processing tool.

As shown in FIG. 4A, a bonding operation is performed to bond the semiconductor die 202 and the semiconductor die 204 at the bonding interface 206a such that the semiconductor die 202 and the semiconductor die 204 are vertically arranged or stacked in the semiconductor device 200. The bonding operation may include similar bonding techniques as described in connection with FIG. 2A.

In some implementations, the semiconductor device 200 may be flipped so that back side processing may be performed on the back side of the semiconductor die 204 after the semiconductor dies 202 and 204 are bonded at the bonding interface 206a. Back side processing may include forming one or more integrated circuit devices in and/or on the back side of the substrate layer 242 of the semiconductor die 204. For example, one or more of the reset transistor 112, the source-follower gate 116 (not shown), the row-select gate 118 (not shown), the intermediate transistor 122, the second floating diffusion node 124, the conversion gain transistor 126, and/or the capacitor 128 may be formed in and/or on the back side of the substrate layer 242.

As shown in FIG. 4B, a portion of the dielectric region 256 of the interconnect layer 254 may be formed over the back side of the substrate layer 242 of the semiconductor die 204.

As shown in FIG. 4C, one or more elongated conductive structures 264 (e.g., one or more TSVs) may be formed through the substrate layer 242 of the semiconductor die 204 such that the one or more elongated conductive structures 264 land on one or more conductive structures 246 in the interconnect layer 240 on the front side of the semiconductor die 204.

To form an elongated conductive structure 264, a recess may be formed through the dielectric region 256, through the substrate layer 242 from the back side of the substrate layer 242, and into the dielectric region 244 of the interconnect layer 240. The recess may extend through the STI region 266 in the substrate layer 242, and into the dielectric region 244 in the interconnect layer 240. A conductive structure 246 in the interconnect layer 240 may be exposed through the recess.

In some implementations, a pattern in a photoresist layer is used to etch the dielectric region 256, the substrate layer 242, the STI region 266, and/or the dielectric region 244 to form the recess. In these implementations, a deposition tool may be used to form the photoresist layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the dielectric region 256, through the substrate layer 242, through the STI region 266, and/or into the dielectric region 244 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the material of the elongated conductive structure 264 in the recess using a CVD technique, a PVD technique, an ALD technique, an electroplating technique, and/or another suitable deposition technique. The elongated conductive structure 264 may be deposited in one or more deposition operations. In some implementations, a seed layer is first deposited, and the elongated conductive structure 264 is deposited on the seed layer. In some implementations, one or more liners 268 (e.g., adhesion liners, barrier liners, diffusion liners) are deposited in the recess, and then the elongated conductive structure 264 is deposited on the liners(s) 268. In some implementations, a planarization tool is used to perform a planarization operation (e.g., a CMP operation) to planarize the elongated conductive structure 264 after the elongated conductive structure 264 is deposited.

As shown in FIG. 4D, additional portions of the interconnect layer 254 may be formed above the back side of the substrate layer 242. One or more semiconductor processing tools may be used to form the interconnect layer 254 by forming one or more dielectric layers of the dielectric region 256 of the interconnect layer 254 and forming a plurality of bonding pads 260 and one or more bonding vias 262 in the dielectric layer(s) of the dielectric region 256. For example, a deposition tool may be used to deposit a first dielectric layer of the dielectric region 256 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a layer (e.g., a via layer, a metallization layer) of one or more bonding vias 262 in the recesses (e.g., using a CVD technique, an ALD technique, a PVD technique, an electroplating technique, and/or another type of deposition technique). At least a portion of the layer of bonding vias 262 may be electrically connected and/or physically connected with the elongated conductive structure 264. Similar processing operations may be performed to form additional layers of the interconnect layer 254 until a sufficient or desired arrangement of bonding pads 260 and bonding vias 262 is achieved. As shown in FIG. 4D, the bonding pads 260 may be formed above and/or on the bonding vias 262.

As indicated above, FIGS. 4A-4D are provided as an example. Other examples may differ from what is described with regard to FIGS. 4A-4D.

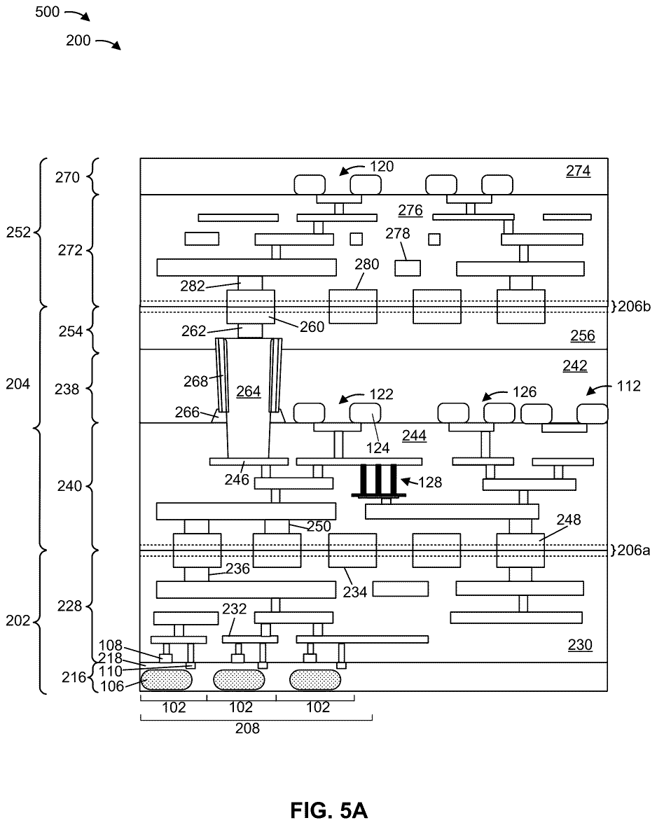

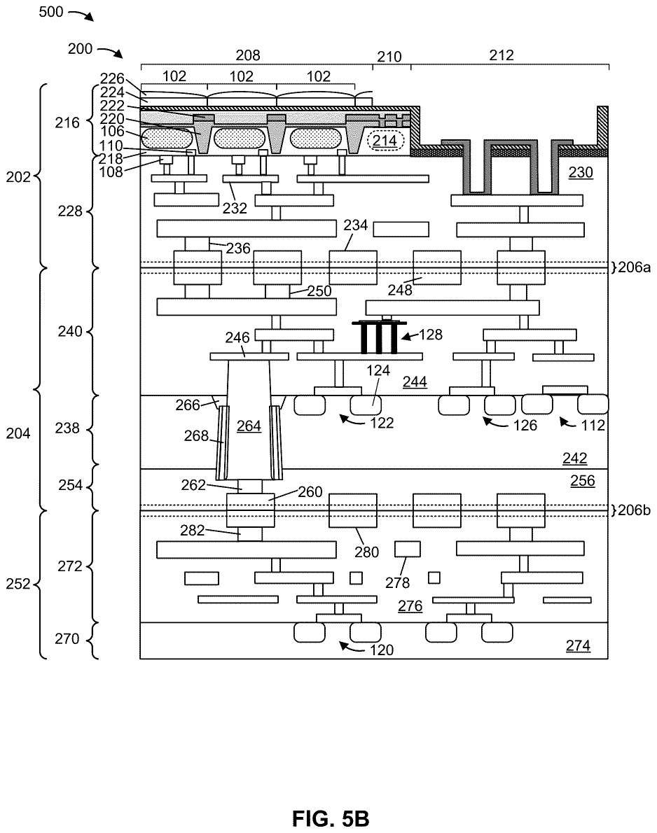

FIGS. 5A and 5B are diagrams of an example implementation 500 of forming the semiconductor device 200 (or a portion thereof) described herein. For example, the example implementation 500 may include an example of bonding the semiconductor dies 204 and 252 of the semiconductor device 200, and performing back side processing on the semiconductor die 202 after bonding. In some implementations, one or more semiconductor processing tools may be used to perform one or more of the operations described in connection with the example implementation 500, such as a deposition tool, an exposure tool, a developer tool, an etch tool, a planarization tool, a bonding tool, and/or another type of semiconductor processing tool.

As shown in FIG. 5A, a bonding operation is performed to bond the semiconductor die 204 and the semiconductor die 252 at the bonding interface 206b such that the semiconductor die 204 and the semiconductor die 252 are vertically arranged or stacked in the semiconductor device 200. The semiconductor die 204 and the semiconductor die 252 may be vertically arranged or stacked in a wafer-on-wafer configuration, a die-on-wafer configuration, a die-on-die configuration, and/or another direct bonding configuration. A bonding tool may be used to perform the bonding operation to bond the semiconductor die 204 and the semiconductor die 252 at the bonding interface 206b. The bonding operation may include forming a direct bond between the semiconductor die 204 and the semiconductor die 252 through a direct physical connection of the bonding pads 260 of the semiconductor die 204 with the bonding pads 280 of the semiconductor die 252, and through a direct physical connection of the dielectric region 256 of the semiconductor die 204 with the dielectric region 276 of the semiconductor die 252. In this way, the interconnect layer 254 on the back side of the semiconductor die 204 and the interconnect layer 272 on the front side of the semiconductor die 252 are facing each other in the semiconductor device 200.

The semiconductor die 252 may be formed by similar operations and/or using similar techniques as described in connection with FIGS. 3A-3D for the semiconductor die 204.

As shown in FIG. 5B, back side processing may be performed on the back side of the semiconductor die 204 after the semiconductor dies 204 and 252 are bonded at the bonding interface 206b. The back side processing may include additional processing described in connection with FIG. 2A to form the pixel sensor array 208, the BLC region 210, and/or the bonding pad region 212. For example, the DTI structure 220 may be formed in the back side of the substrate layer 218 such that the DTI structure 220 laterally surrounds the photodiodes 106 of the pixel sensors 100. As another example, the grid structure 222 may be formed above the back side of the substrate layer 218, the color filter regions 224 may be above the photodiodes 106 on the back side of the substrate layer 218, and the micro-lenses 226 may be formed above the color filter regions 224. As another example, a metal shielding layer may be formed over the region 214 in the BLC region 210. As another example, a bonding pad structure may be formed in the bonding pad region 212.

As indicated above, FIGS. 5A and 5B are provided as an example. Other examples may differ from what is described with regard to FIGS. 5A and 5B.

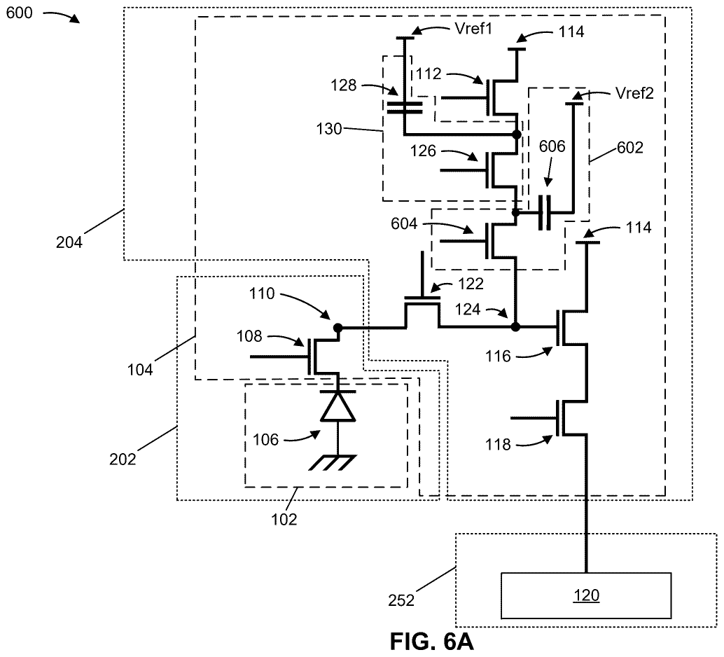

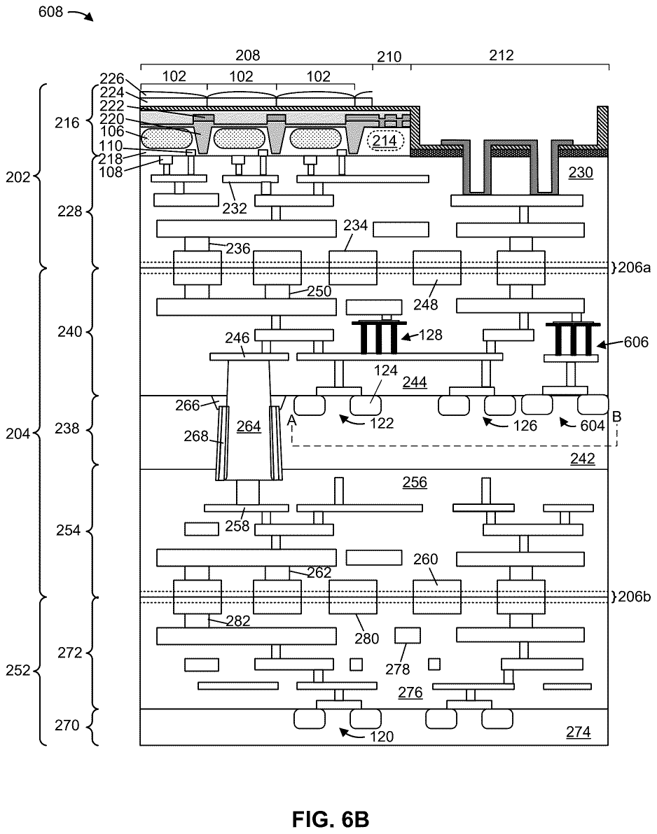

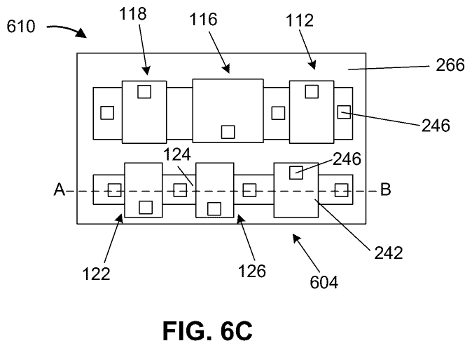

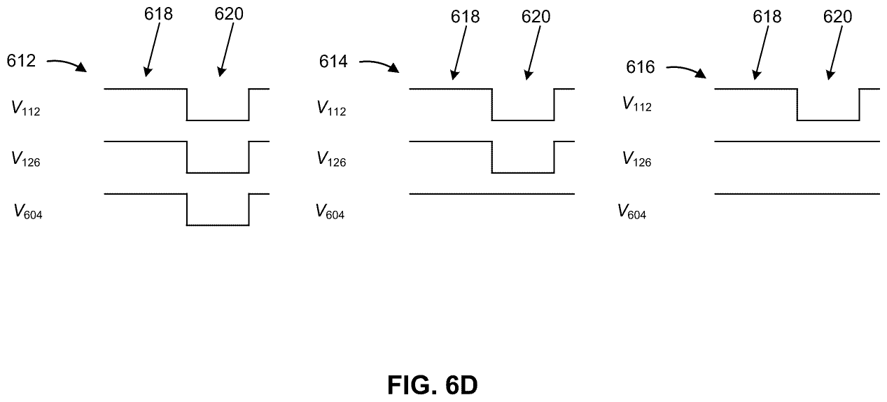

FIG. 6A is a diagram of an example implementation 600 of a pixel sensor 100 described herein. FIG. 6A illustrates an example distribution of components across a plurality of semiconductor dies.

As shown in FIG. 6A, the sensing region 102 of a pixel sensor 100 may be included on the semiconductor die 202 (e.g., an image sensor die). Moreover, the transfer gate 108 of the control circuitry region 104 of the pixel sensor 100 may be included on the semiconductor die 202.

The first floating diffusion node 110 of the control circuitry region 104 of the pixel sensor 100 is included on the semiconductor die 202. Another portion of the control circuitry region 104 of the pixel sensor 100 may be included on the semiconductor die 204.

The reset transistor 112, the source-follower gate 116, the row-select gate 118, the intermediate transistor 122, the second floating diffusion node 124, and the conversion gain circuit 130 (including the conversion gain transistor 126 and the capacitor 128) may also be included on the semiconductor die 204.

In the example implementation 600, the pixel sensor 100 further includes another conversion gain circuit 602, which includes a conversion gain transistor 604 and a capacitor 606, on the semiconductor die 204. A first source/drain terminal (region) of the conversion gain transistor 604 is electrically coupled to a first source/drain terminal (region) of the conversion gain transistor 126. The first source/drain terminal of the conversion gain transistor 604 is also electrically coupled to the capacitor 606. A second source/drain terminal (region) of the conversion gain transistor 604 is electrically coupled to the second floating diffusion node 124. A second source/drain terminal (region) of the conversion gain transistor 126 is electrically coupled to the capacitor 128. The capacitor 128 is electrically coupled to a reference voltage source (Vref1). The capacitor 606 is electrically coupled to a reference voltage source (Vref2). The capacitor 606 is electrically coupled to the second floating diffusion node 124 through the conversion gain transistor 604. The capacitor 128 is electrically coupled to the second floating diffusion node 124 through the conversion gain transistor 126 and through the conversion gain transistor 604.

In some implementations, Vref1 and Vref2 may be the same reference voltage source. In some implementations, Vref1 and Vref2 may be different reference voltage sources. In some implementations, Vref1 and/or Vref2 may be the same as the supply voltage source 114. In some implementations, Vref1 and/or Vref2 may be different than the supply voltage source 114.

The conversion gain transistors 126 and 604 enable the conversion gain circuits 130 and 602 to be selectively activated or deactivated, respectively. In addition, based on the capacitor 128 being electrically coupled to the second floating diffusion node 124 through the conversion gain transistor 126 and through the conversion gain transistor 604, deactivation of the conversion gain transistor 604 deactivates both of the conversion gain circuits 130 and 602. For example, when the conversion gain transistor 126 is activated, and the conversion gain transistor 604 is activated, the capacitor 128 and the capacitor 606 may be connected to the second floating diffusion node 124, thereby enabling the capacitors 128 and 606 to each function as a LOFIC for the second floating diffusion node 124. In another example, when the conversion gain transistor 126 is deactivated, and the conversion gain transistor 604 is activated, the capacitor 606 may be connected to the second floating diffusion node 124, thereby enabling the capacitor 606 to function as a LOFIC for the second floating diffusion node 124. In a further example, when the conversion gain transistor 604 is deactivated, and the conversion gain transistor 126 is activated or deactivated, both of the conversion gain circuits 130 and 602 are deactivated so that neither of the capacitors 128 and 606 function as a LOFIC for the second floating diffusion node 124. When functioning as a LOFIC for the second floating diffusion node 124, the capacitor 128 and/or the capacitor 606 may store overflow charge from the second floating diffusion node 124, thereby enabling additional charge generated by the photodiode 106 to be stored in the second floating diffusion node 124 without the second floating diffusion node 124 reaching saturation. When the conversion gain transistor 126 is deactivated and/or the conversion gain transistor 604 is deactivated, the capacitor 128 may be disconnected from the second floating diffusion node 124. When the conversion gain transistor 604 is deactivated, the capacitor 128 and the capacitor 606 may be disconnected from the second floating diffusion node 124.

The conversion gain transistors 126 and 604 are electrically coupled to the second floating diffusion node 124 in series, and the capacitor 128 and the capacitor 606 are electrically coupled to the second floating diffusion node 124 and the supply voltage source 114 in parallel. The capacitance (C₁) of the capacitor 128 and the capacitance (C₂) of the capacitor 606 may be different, which enables various combinations (e.g., up to 3 combinations) of capacitance to be achieved in the pixel sensor 100 for sequential conversion gain operations. In some implementations, the capacitance of the capacitor 128 is greater than the capacitance of the capacitor 606. In some implementations, the capacitance of the capacitor 606 is greater than the capacitance of the capacitor 128. In some implementations, additional conversion gain circuits that are similarly arranged may be included in the control circuitry region 104 of the pixel sensor 100 to enable more than 3 combinations of capacitances to be selected for the sequential conversion gain operations.

The capacitor 128 and the reset transistor 112 may be electrically coupled to the second source/drain terminal of the conversion gain transistor 126 and to the supply voltage source 114 in parallel. The second floating diffusion node 124 may be reset by activating the conversion gain transistor 126, the conversion gain transistor 604, and the reset transistor 112.

The image processing circuit 120 may be included on a semiconductor die 252.

FIG. 6B illustrates a cross-sectional view of a structural implementation of a semiconductor device 608 including an image sensor device such as a CMOS image sensor device that includes the one or more pixel sensors 100 shown in the example implementation 600.

As shown in FIG. 6B, the semiconductor dies 202, 204, and 252 of the semiconductor device 608 may include a similar combination and arrangement of layers and/or structures as the semiconductor device 200. However, as indicated above in FIG. 6A, the example implementation 600 of the pixel sensor 100 further includes the conversion gain circuit 602 (including the conversion gain transistor 604 and the capacitor 606) on the second semiconductor die 204. For example, in addition to the capacitor 128 of the conversion gain circuit 130, the capacitor 606 of the conversion gain circuit 602 may be included in the interconnect layer 240 of the semiconductor die 204. In other words, the capacitor 606 may be included on the front side of the semiconductor die 204. The reset transistor 112, the source-follower gate 116, the row-select gate 118, the intermediate transistor 122, the second floating diffusion node 124, the conversion gain transistor 126, and/or the conversion gain transistor 604 may be included in and/or on the substrate layer 242 of the semiconductor die 204. In some implementations, the reset transistor 112, the source-follower gate 116, the row-select gate 118, the intermediate transistor 122, the second floating diffusion node 124, the conversion gain transistor 126, and/or the conversion gain transistor 604 may be included in and/or on a front side of the substrate layer 242 facing the interconnect layer 240. In some implementations, the reset transistor 112, the source-follower gate 116, the row-select gate 118, the intermediate transistor 122, the second floating diffusion node 124, the conversion gain transistor 126, and/or the conversion gain transistor 604 may be included in and/or on a back side of the substrate layer 242 facing the interconnect layer 254.

Additionally and/or alternatively, one or more of the capacitors 128 and/or capacitors 606 may be included in the device layer 216 (e.g., in the substrate layer 218) of the semiconductor die 202. The capacitors 128 and/or capacitors 606 may be electrically coupled to the second floating diffusion nodes 124 of the pixel sensors 100 through one or more conductive structures 246 in the interconnect layer 240. The capacitors 128 and/or the capacitors 606 may be implemented as various types of capacitor structures, such as planar capacitor structures, trench capacitor structures, deep trench capacitor (DTC) structures, and/or another type of capacitor structures. In some implementations, a source/drain region (or source/drain terminal) of the intermediate transistor 122 may include the second floating diffusion node 124. In other implementations, the second floating diffusion node 124 may be a separate region from the source/drain region (or source/drain terminal) of the intermediate transistor 122.

FIG. 6C is a diagram of an example implementation 610 of a portion of the semiconductor device 608 described herein. In the example implementation 610, FIG. 6C is a top view of a portion of the semiconductor device 608 including the reset transistor 112, the source-follower gate 116, the row-select gate 118, the intermediate transistor 122, the second floating diffusion node 124, the conversion gain transistor 126, and the conversion gain transistor 604. The substrate layer 242 includes source/drain regions corresponding to adjacent gates of a given transistor. A source/drain region of the intermediate transistor 122 includes the second floating diffusion node 124. The conductive structures 246 contacting the gates and source/drain regions respectively correspond to source/drain interconnects and/or gate interconnects. An STI region 266 is formed around the reset transistor 112, the source-follower gate 116, the row-select gate 118, the intermediate transistor 122, the second floating diffusion node 124, the conversion gain transistor 126, and the conversion gain transistor 604. A cross-section taken along the line A-B in FIG. 6C is illustrated by the portion of FIG. 6B including the intermediate transistor 122, the second floating diffusion node 124, the conversion gain transistor 126, and the conversion gain transistor 604 in the substrate layer 242.

FIG. 6D depicts an example timing diagram 612 corresponding to a first conversion gain operation (e.g., an HCG operation) in the pixel sensor 100 of the example implementation 600, an example timing diagram 614 corresponding to a second conversion gain operation (e.g., a medium conversion gain (MCG) operation) in the pixel sensor 100 of the example implementation 600, and an example timing diagram 616 corresponding to a third conversion gain operation (e.g., an LCG operation) in the pixel sensor 100 of the example implementation 600. The control circuitry region 104 of the pixel sensor 100 in the example implementation 600 includes a plurality of conversion gain circuits, including a conversion gain circuit 130 and a conversion gain circuit 602. The conversion gain circuits 130 and 602 can be selectively activated or deactivated in various combinations to enable a plurality of sequential conversion gain operations to be performed for an exposure operation of the pixel sensor 100 (e.g., an exposure operation to generate an image and/or a video). The conversion gain circuits 130 and 602 enable the capacitance of the pixel sensor 100 to be gradually increased through the exposure operation, which gradually increases the full-well capacity (FWC) of the pixel sensor 100. The increased capacitance enables additional charge to be stored in the control circuitry region 104 during the exposure operation, which enables the level of the photocurrent to be increased during the exposure operation. In this way, the conversion gain can be inversely decreased so that a high dynamic range can be achieved in the exposure operation.

The timing diagrams 612, 614, and 616 each include reset periods 618 and read periods 620. The designations V₁₁₂, V₁₂₆, and V₆₀₄ correspond to high or low voltage levels being applied to the gate of the reset transistor 112, to the gate of the conversion gain transistor 126, and to the gate of the conversion gain transistor 604 to respectively activate or deactivate the corresponding transistors. During the first conversion gain operation, the reset transistor 112, the conversion gain transistor 126, and the conversion gain transistor 604 are deactivated during the read period 620. During the second conversion gain operation, the reset transistor 112 is deactivated, the conversion gain transistor 126 is deactivated, and the conversion gain transistor 604 is activated during the read period 620. During the third conversion gain operation, the reset transistor 112 is deactivated, the conversion gain transistor 126 is activated, and the conversion gain transistor 604 is activated during the read period 620. Based on the arrangement of the conversion gain transistors 126 and 604, there is no separate timing diagram for when the conversion gain transistor 126 is activated, and the conversion gain transistor 604 is deactivated during the read period 620 because deactivation of the conversion gain transistor 604 also deactivates the conversion gain transistor 126. When the conversion gain transistor 604 is deactivated, the capacitor 128 and the capacitor 606 may be disconnected from the second floating diffusion node 124.

As indicated above, FIGS. 6A-6D are provided as an example. Other examples may differ from what is described with regard to FIGS. 6A-6D.

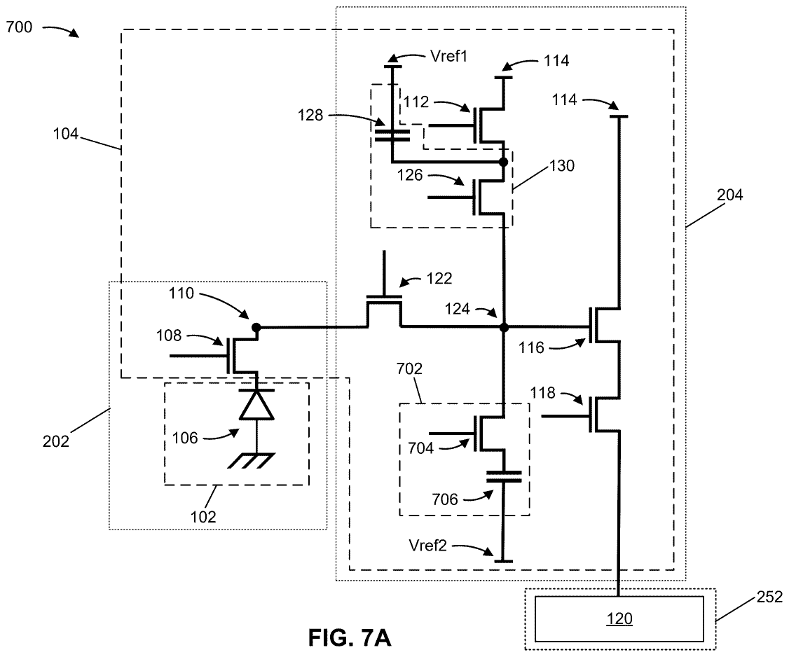

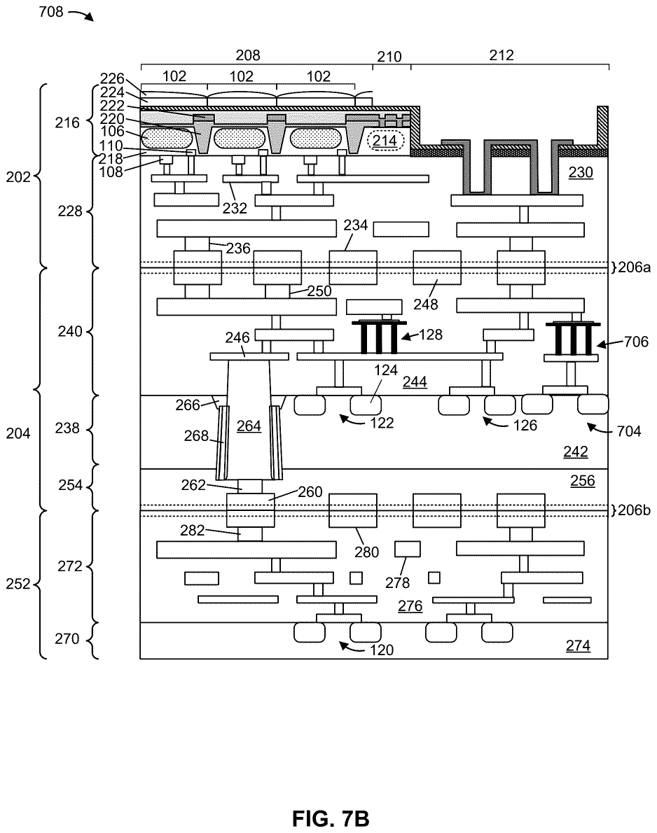

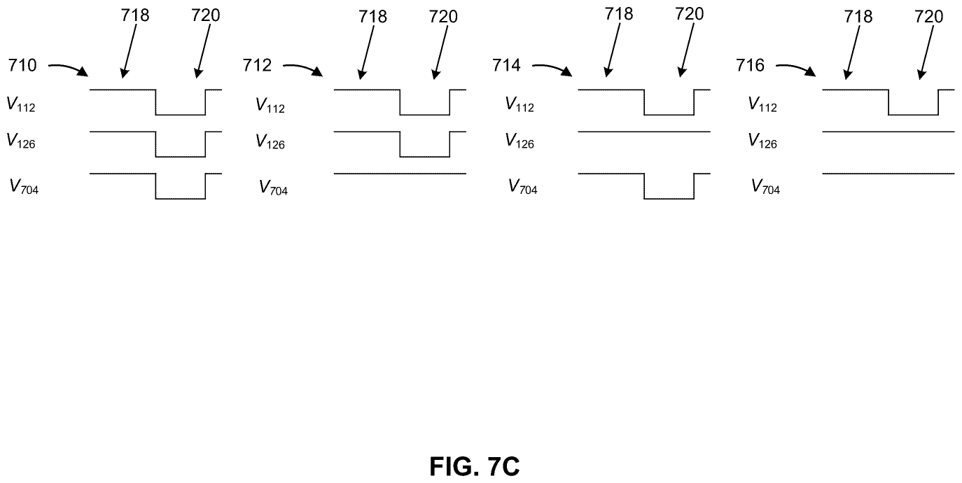

FIG. 7A is a diagram of an example implementation 700 of a pixel sensor 100 described herein. FIG. 7A illustrates an example distribution of components across a plurality of semiconductor dies.

As shown in FIG. 7A, the sensing region 102 of a pixel sensor 100 may be included on the semiconductor die 202 (e.g., an image sensor die). Moreover, the transfer gate 108 of the control circuitry region 104 of the pixel sensor 100 may be included on the semiconductor die 202.

The first floating diffusion node 110 of the control circuitry region 104 of the pixel sensor 100 is included on the semiconductor die 202. Another portion of the control circuitry region 104 of the pixel sensor 100 may be included on the semiconductor die 204.

The reset transistor 112, the source-follower gate 116, the row-select gate 118, the intermediate transistor 122, the second floating diffusion node 124, and the conversion gain circuit 130 (including the conversion gain transistor 126 and the capacitor 128) may also be included on the semiconductor die 204.

In the example implementation 700, the pixel sensor 100 further includes another conversion gain circuit 702, which includes a conversion gain transistor 704 and a capacitor 706, on the semiconductor die 204. A first source/drain terminal (region) of the conversion gain transistor 126 is electrically coupled to the second floating diffusion node 124, and a second source/drain terminal (region) of the conversion gain transistor 126 is electrically coupled to the capacitor 128. The capacitor 128 is electrically coupled to a reference voltage source (Vref1). The capacitor 128 is electrically coupled to the second floating diffusion node 124 through the conversion gain transistor 126.

A first source/drain terminal (region) of the conversion gain transistor 704 is electrically coupled to the second floating diffusion node 124, and a second source/drain terminal (region) of the conversion gain transistor 704 is electrically coupled to the capacitor 706. The capacitor 706 is electrically coupled to a reference voltage source (Vref2). The capacitor 706 is electrically coupled to the second floating diffusion node 124 through the conversion gain transistor 704.

In some implementations, Vref1 and Vref2 may be the same reference voltage source. In some implementations, Vref1 and Vref2 may be different reference voltage sources. In some implementations, Vref1 and/or Vref2 may be the same as the supply voltage source 114. In some implementations, Vref1 and/or Vref2 may be different than the supply voltage source 114.

The conversion gain transistors 126 and 704 enable the conversion gain circuits 130 and 702 to be selectively activated or deactivated, respectively. For example, when the conversion gain transistor 126 is activated, the capacitor 128 may be connected to the second floating diffusion node 124, thereby enabling the capacitor 128 to function as a lateral overflow integration capacitor (LOFIC) for the second floating diffusion node 124. In particular, the capacitor 128 may store overflow charge from the second floating diffusion node 124, thereby enabling additional charge generated by the photodiode 106 to be stored in the second floating diffusion node 124 without the second floating diffusion node 124 reaching saturation. When the conversion gain transistor 126 is deactivated, the capacitor 128 may be disconnected from the second floating diffusion node 124.

Similarly, when the conversion gain transistor 704 is activated, the capacitor 706 may be connected to the second floating diffusion node 124, thereby enabling the capacitor 706 to function as a LOFIC for the second floating diffusion node 124. In particular, the capacitor 706 may store overflow charge from the second floating diffusion node 124, thereby enabling additional charge generated by the photodiode 106 to be stored in the second floating diffusion node 124 without the second floating diffusion node 124 reaching saturation. When the conversion gain transistor 704 is deactivated, the capacitor 706 may be disconnected from the second floating diffusion node 124.

The conversion gain transistors 126 and 704 are electrically coupled to the second floating diffusion node 124 in parallel. Thus, the capacitor 128 and the capacitor 706 are electrically coupled to the second floating diffusion node 124 and the supply voltage source 114 in parallel. The capacitance (C₁) of the capacitor 128 and the capacitance (C₂) of the capacitor 706 may be different, which enables various combinations (e.g., up to 4 combinations) of capacitance to be achieved in the pixel sensor 100 of the example implementation 700 for the sequential conversion gain operations. In some implementations, the capacitance of the capacitor 128 is greater than the capacitance of the capacitor 706. In some implementations, the capacitance of the capacitor 706 is greater than the capacitance of the capacitor 128. In some implementations, additional conversion gain circuits that are similarly arranged may be included in the control circuitry region 104 of the pixel sensor 100 to enable more than 4 combinations of capacitances to be selected for the sequential conversion gain operations.

The capacitor 128 and the reset transistor 112 may be electrically coupled to the second source/drain terminal of the conversion gain transistor 126 and to the supply voltage source 114 in parallel. The second floating diffusion node 124 may be reset by activating the conversion gain transistor 126 and the reset transistor 112.

The image processing circuit 120 may be included on a semiconductor die 252.

FIG. 7B illustrates a cross-sectional view of a structural implementation of a semiconductor device 708 including an image sensor device such as a CMOS image sensor device that includes the one or more pixel sensors 100 shown in the example implementation 700.

As shown in FIG. 7B, the semiconductor dies 202, 204, and 252 of the semiconductor device 708 may include a similar combination and arrangement of layers and/or structures as the semiconductor device 200. However, as indicated above with respect to FIG. 7A, the example implementation 700 of the pixel sensor 100 further includes the conversion gain circuit 702 (including the conversion gain transistor 704 and the capacitor 706) on the second semiconductor die 204. For example, in addition to the capacitor 128 of the conversion gain circuit 130, the capacitor 706 of the conversion gain circuit 702 may be included in the interconnect layer 240 of the semiconductor die 204. In other words, the capacitor 706 may be included on the front side of the semiconductor die 204. The reset transistor 112, the source-follower gate 116, the row-select gate 118, the intermediate transistor 122, the second floating diffusion node 124, the conversion gain transistor 126, and/or the conversion gain transistor 704 may be included in and/or on the substrate layer 242 of the semiconductor die 204. In some implementations, the reset transistor 112, the source-follower gate 116, the row-select gate 118, the intermediate transistor 122, the second floating diffusion node 124, the conversion gain transistor 126, and/or the conversion gain transistor 704 may be included in and/or on a front side of the substrate layer 242 facing the interconnect layer 240. In some implementations, the reset transistor 112, the source-follower gate 116, the row-select gate 118, the intermediate transistor 122, the second floating diffusion node 124, the conversion gain transistor 126, and/or the conversion gain transistor 704 may be included in and/or on a back side of the substrate layer 242 facing the interconnect layer 254.

Additionally and/or alternatively, one or more of the capacitors 128 and/or capacitors 706 may be included in the device layer 216 (e.g., in the substrate layer 218) of the semiconductor die 202. The capacitors 128 and/or capacitors 706 may be electrically coupled to the second floating diffusion nodes 124 of the pixel sensors 100 through one or more conductive structures 246 in the interconnect layer 240. The capacitors 128 and/or the capacitors 706 may be implemented as various types of capacitor structures, such as planar capacitor structures, trench capacitor structures, deep trench capacitor (DTC) structures, and/or other types of capacitor structures. In some implementations, a source/drain region (or source/drain terminal) of the intermediate transistor 122 may include the second floating diffusion node 124. In other implementations, the second floating diffusion node 124 may be a separate region from the source/drain region (or source/drain terminal) of the intermediate transistor 122.

FIG. 7C depicts an example timing diagram 710 corresponding to a first conversion gain operation (e.g., an HCG operation) in the pixel sensor 100 of the example implementation 700, an example timing diagram 712 corresponding to a second conversion gain operation (e.g., a medium conversion gain (MCG) operation) in the pixel sensor 100 of the example implementation 700, an example timing diagram 714 corresponding to a third conversion gain operation (e.g., a medium-low conversion gain (MLCG) operation) in the pixel sensor 100 of the example implementation 700, and an example timing diagram 716 corresponding to a fourth conversion gain operation (e.g., an LCG operation) in the pixel sensor 100 of the example implementation 700. The control circuitry region 104 of the pixel sensor 100 in the example implementation 700 includes a plurality of conversion gain circuits, including a conversion gain circuit 130 and a conversion gain circuit 702. The conversion gain circuits 130 and 702 can be selectively activated or deactivated in various combinations to enable a plurality of sequential conversion gain operations to be performed for an exposure operation of the pixel sensor 100 (e.g., an exposure operation to generate an image and/or a video). The conversion gain circuits 130 and 702 enable the capacitance of the pixel sensor 100 to be gradually increased through the exposure operation, which gradually increases the FWC of the pixel sensor 100. The increased capacitance enables additional charge to be stored in the control circuitry region 104 during the exposure operation, which enables the level of the photocurrent to be increased during the exposure operation. In this way, the conversion gain can be inversely decreased so that a high dynamic range can be achieved in the exposure operation.

The timing diagrams 710, 712, 714, and 716 each include reset periods 718 and read periods 720. The designations V₁₁₂, V₁₂₆, and V₇₀₄ correspond to high or low voltage levels being applied to the gate of the reset transistor 112, to the gate of the conversion gain transistor 126, and to the gate of the conversion gain transistor 704 to respectively activate or deactivate the corresponding transistors. During the first conversion gain operation, the reset transistor 112, the conversion gain transistor 126, and the conversion gain transistor 704 are deactivated during the read period 720. During the second conversion gain operation, the reset transistor 112 is deactivated, the conversion gain transistor 126 is deactivated, and the conversion gain transistor 704 is activated during the read period 720. During the third conversion gain operation, the reset transistor 112 is deactivated, the conversion gain transistor 126 is activated, and the conversion gain transistor 704 is deactivated during the read period 720. During the fourth conversion gain operation, the reset transistor 112 is deactivated, the conversion gain transistor 126 is activated, and the conversion gain transistor 704 is activated during the read period 720.

As indicated above, FIGS. 7A-7C are provided as an example. Other examples may differ from what is described with regard to FIGS. 7A-7C.

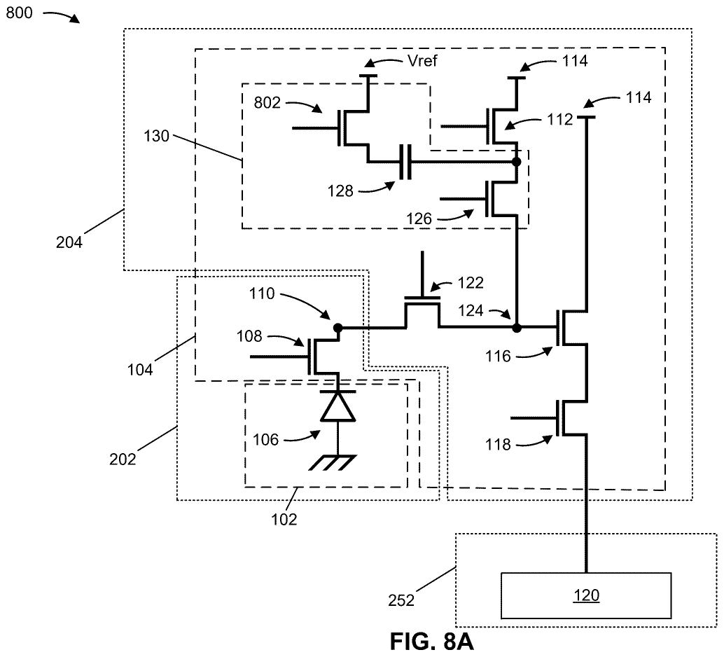

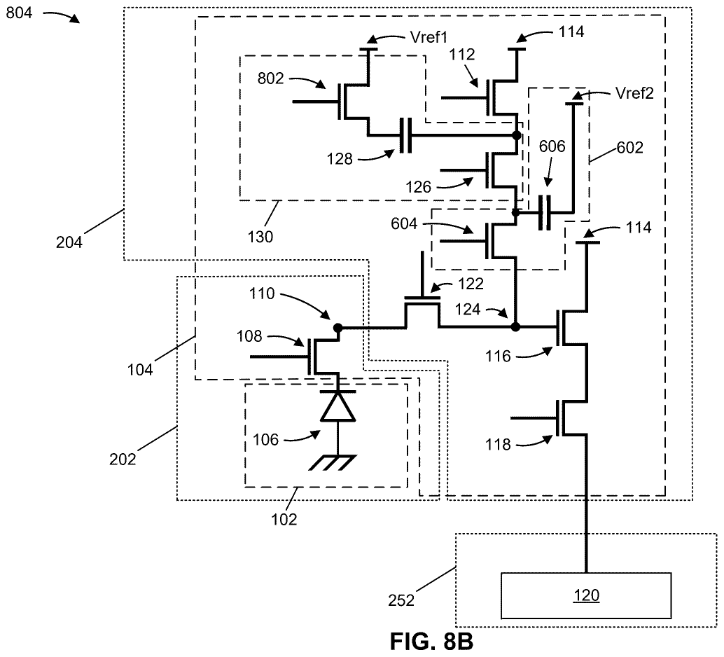

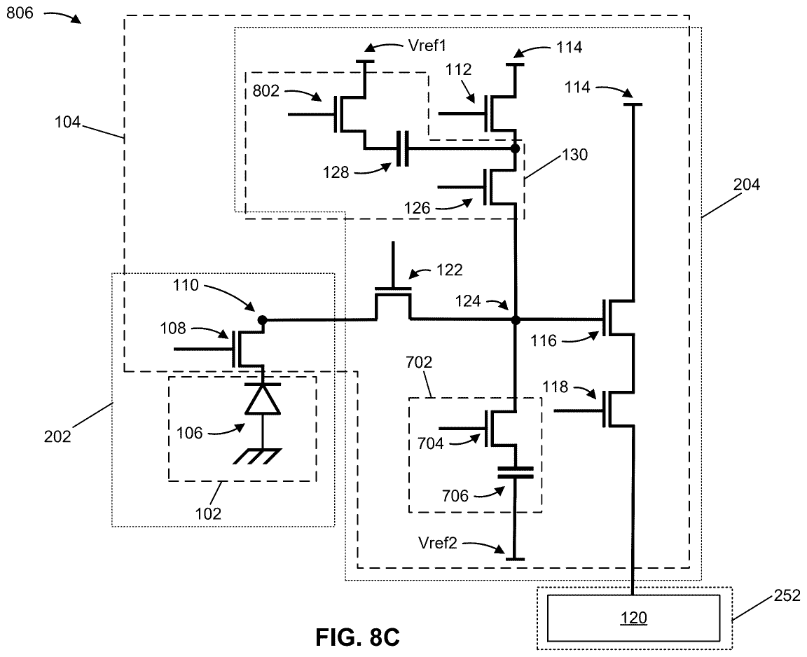

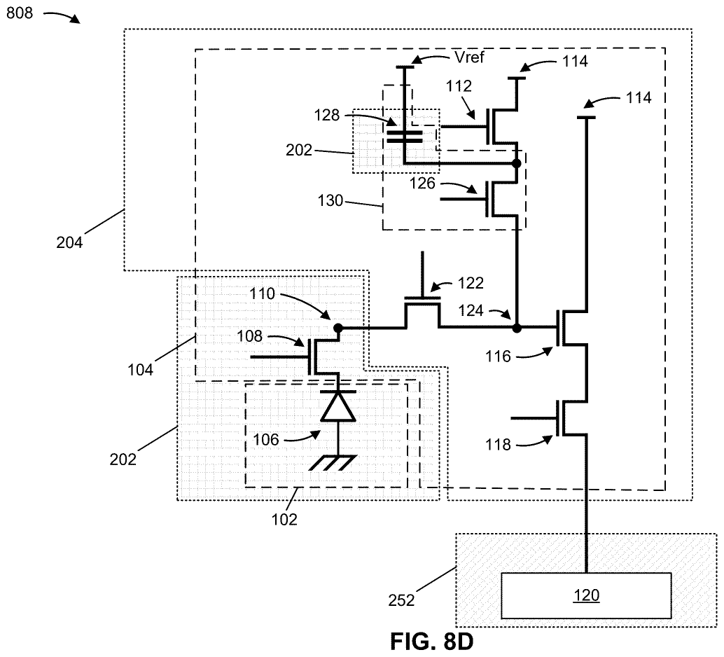

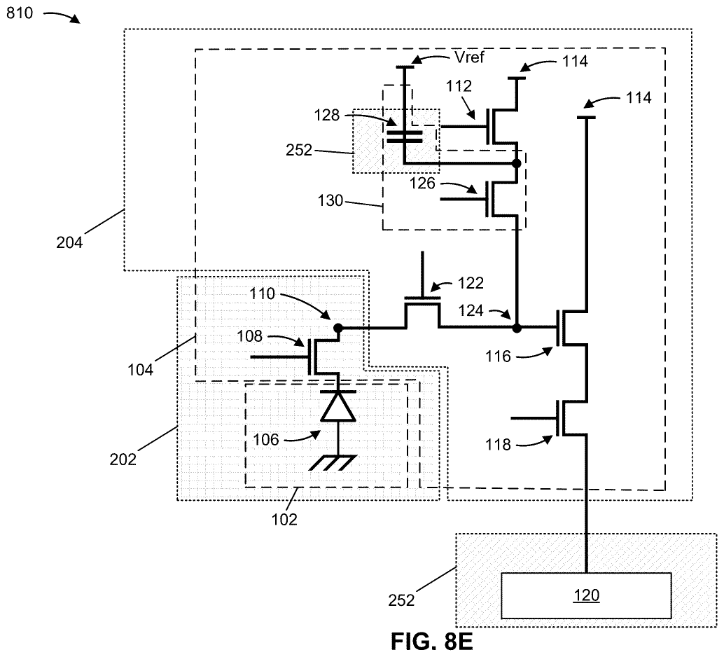

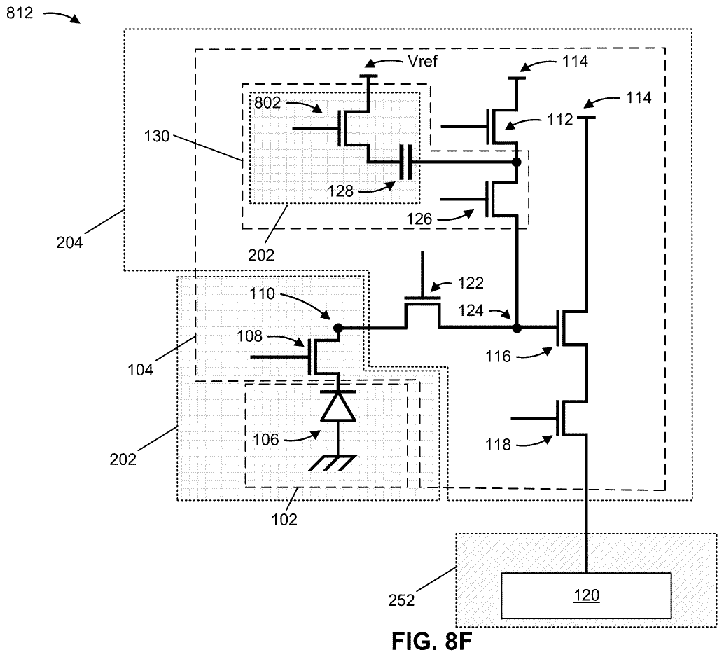

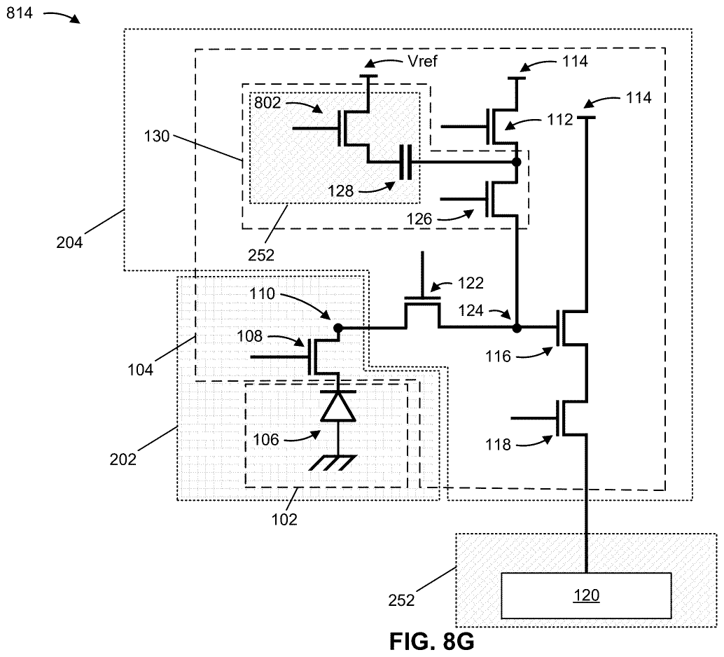

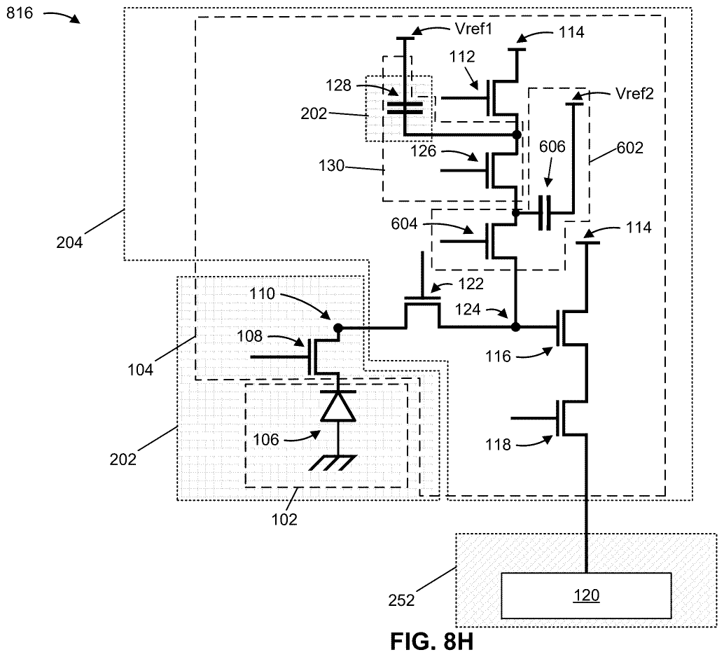

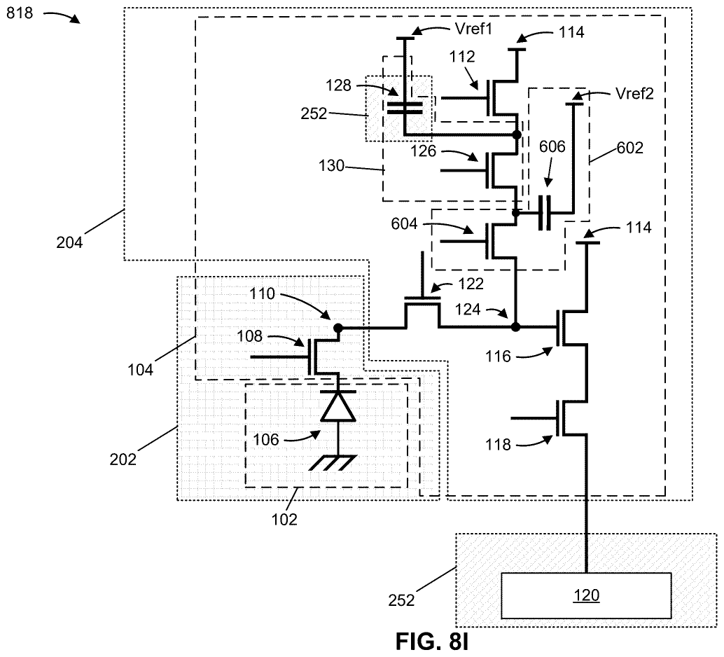

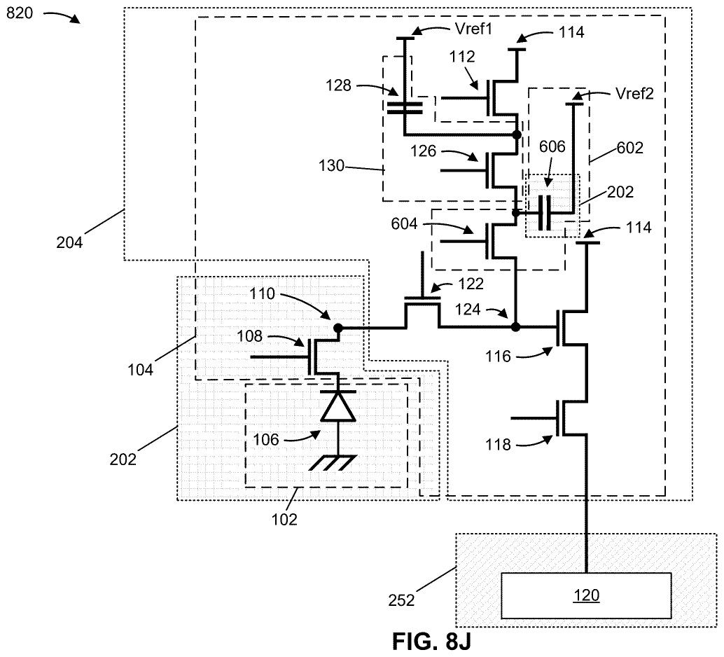

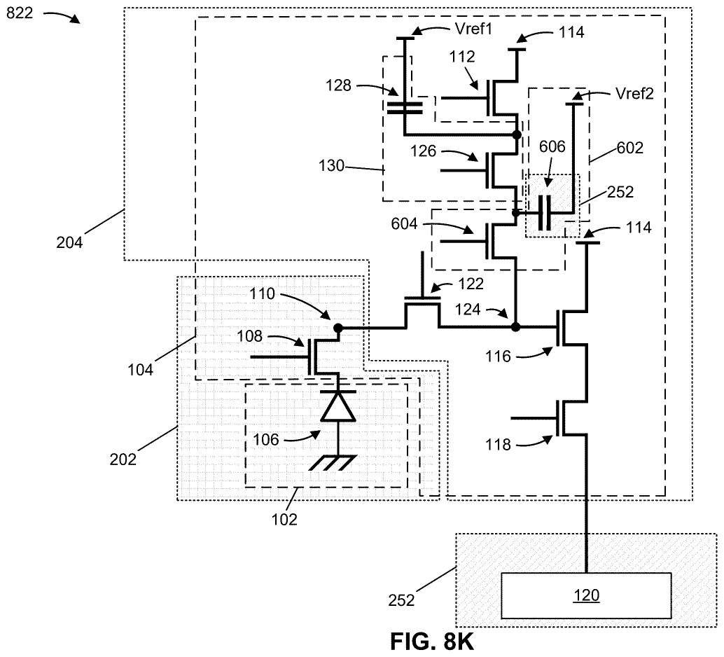

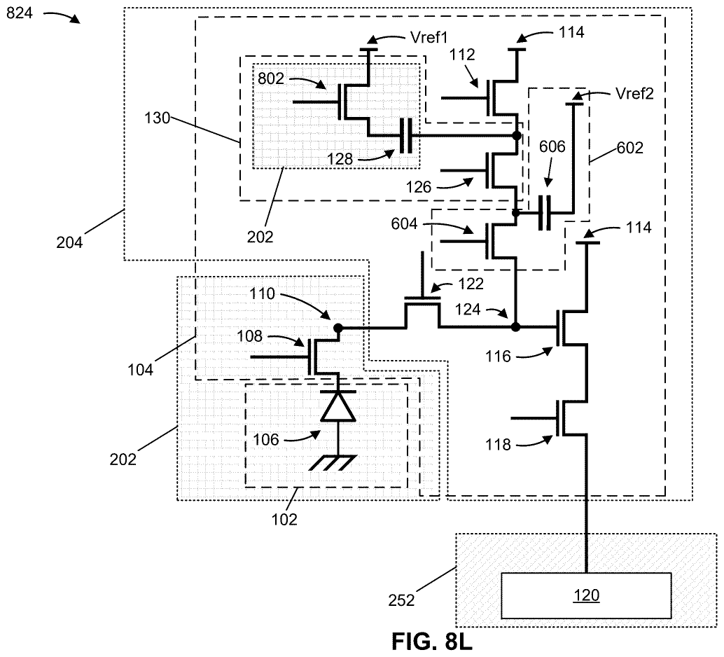

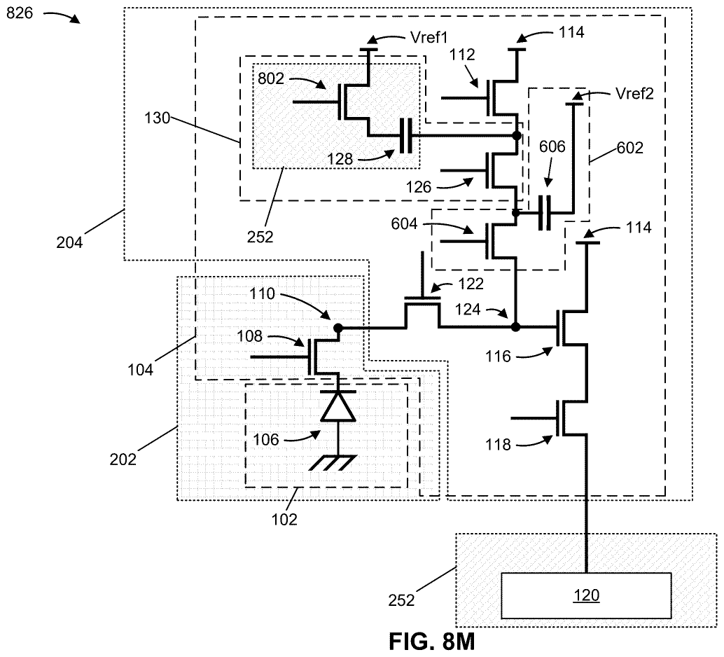

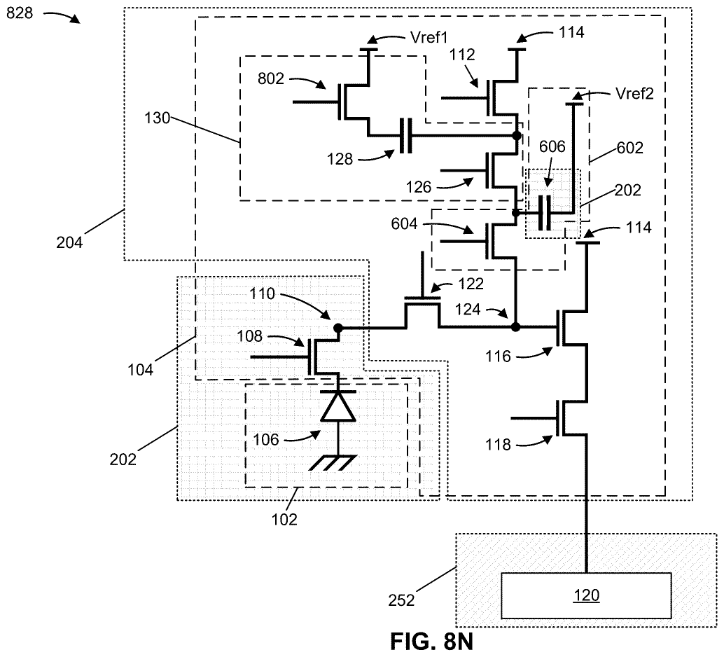

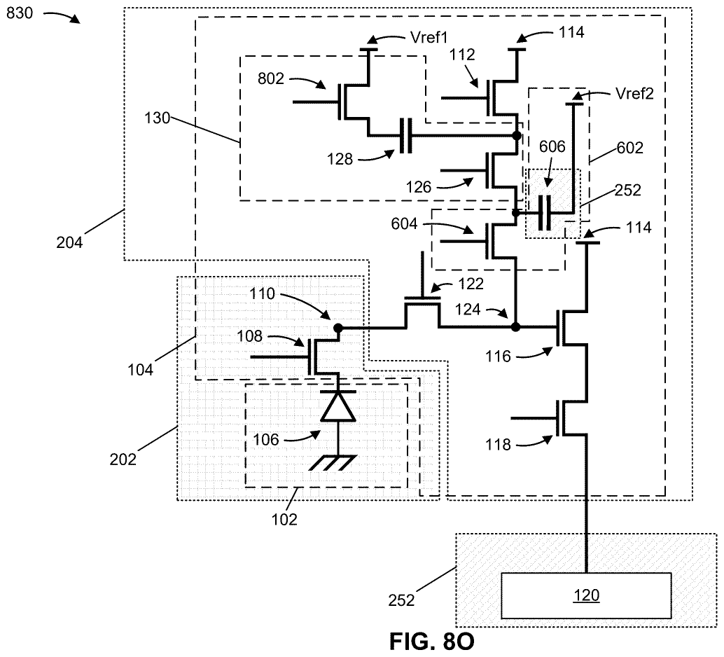

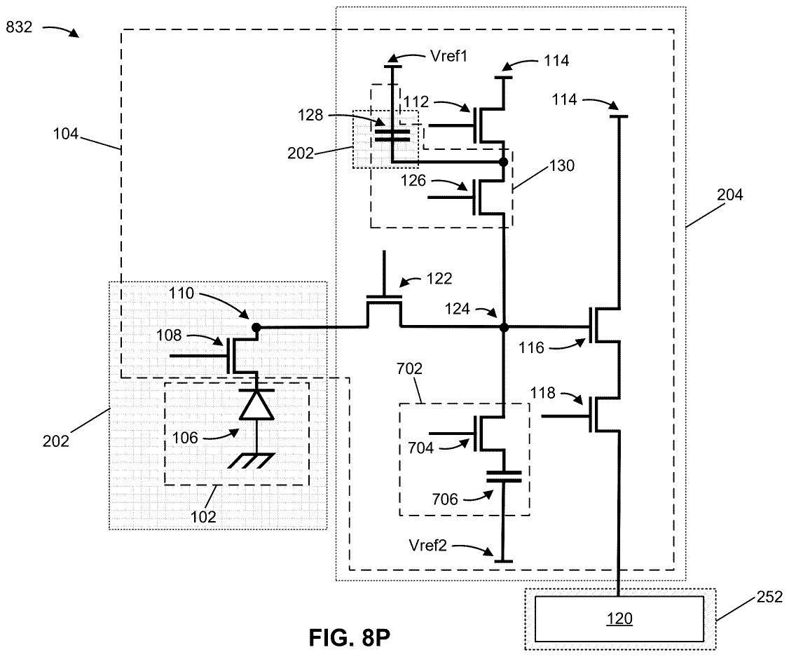

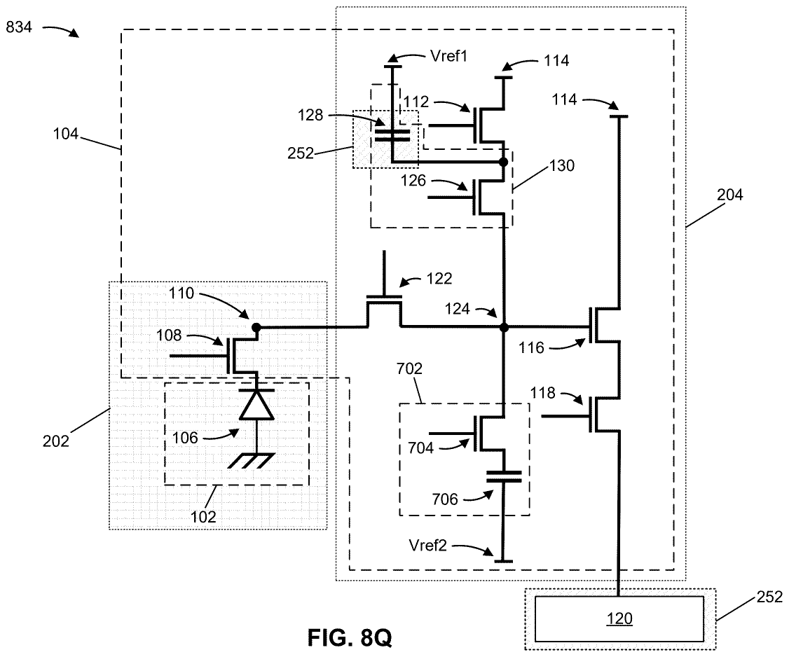

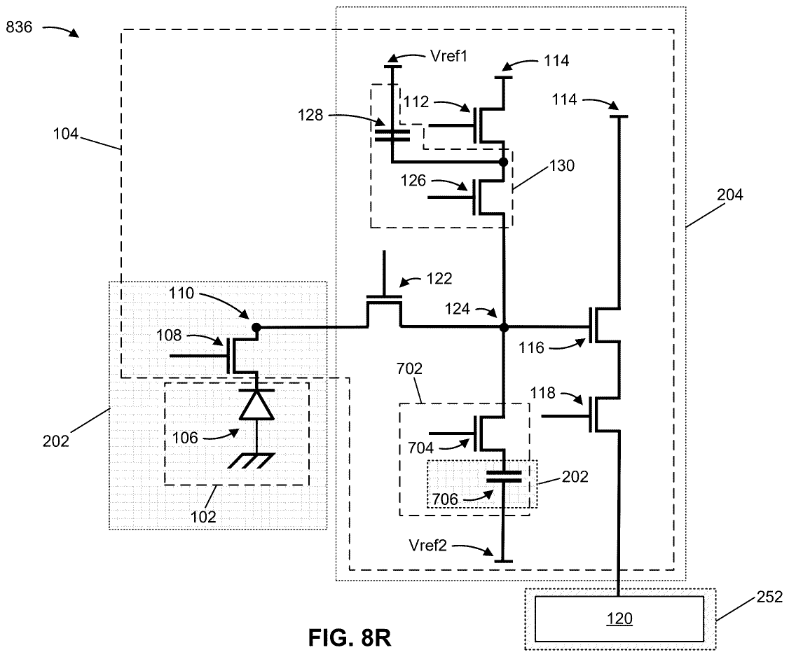

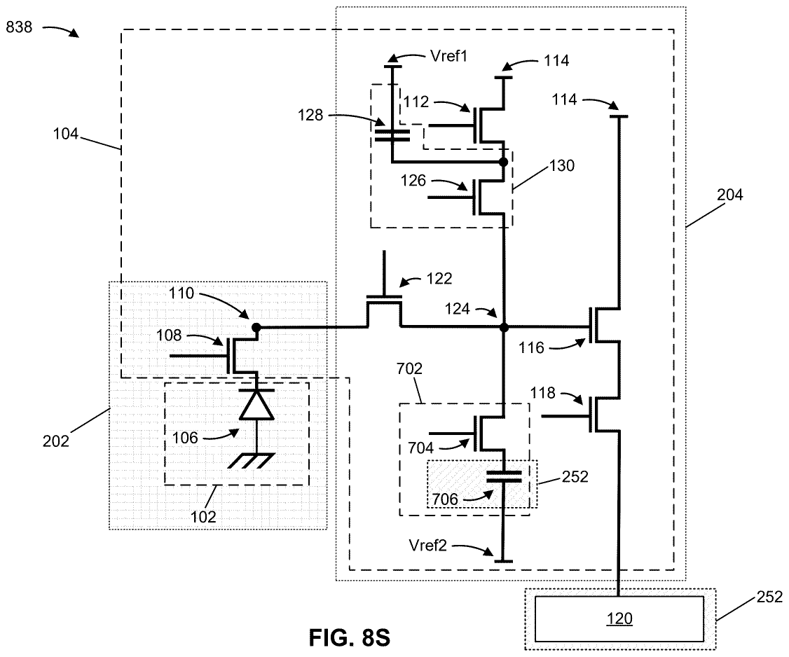

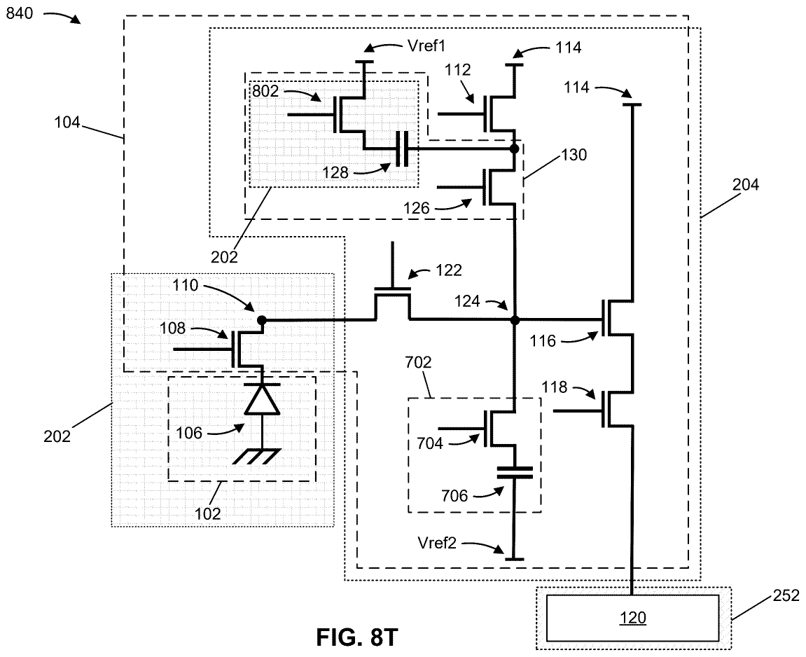

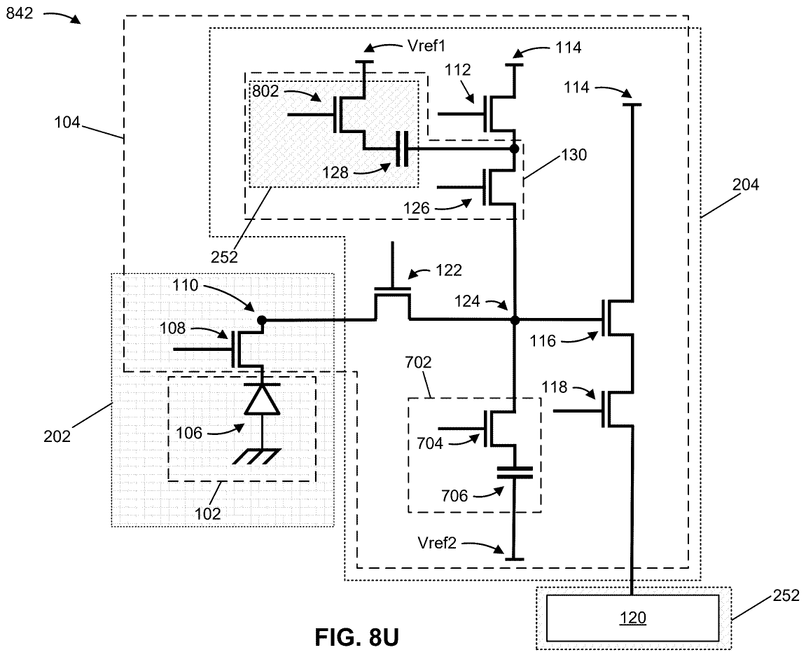

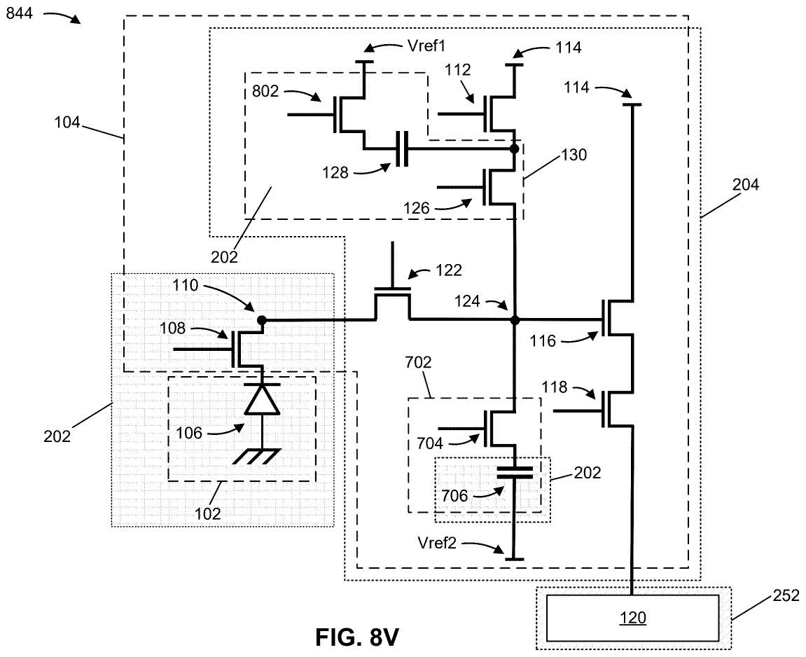

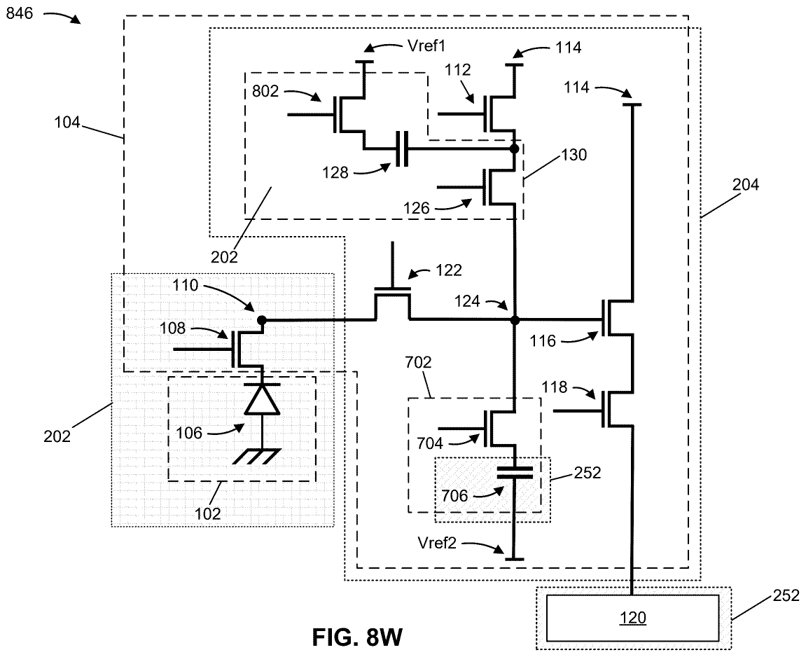

FIGS. 8A-8W are diagrams of example implementations 800, and 804-840 of the pixel sensor 100 described herein. As shown in FIG. 8A, in the example implementation 800, the pixel sensor 100 from FIG. 1A includes an additional transistor 802 in the conversion gain circuit 130, as shown in FIG. 8B, in the example implementation 804, the pixel sensor 100 from the example implementation 600 of FIG. 6A includes the additional transistor 802 in the conversion gain circuit 130, and as shown in FIG. 8C, in the example implementation 806, the pixel sensor 100 from the example implementation 700 of FIG. 7A includes the additional transistor 802 in the conversion gain circuit 130. The additional transistor 802 may be activated, alone or in combination with the reset transistor 112, to reset the capacitor 128 of the conversion gain circuit 130. The use of the additional transistor 802 to reset the capacitor 128 may enable the capacitor 128 to be reset faster, thereby reducing the reset time of the capacitor 128 and improving the responsiveness and speed of the pixel sensor 100.

To reset the capacitor 128, a voltage input may be applied to the gate of the transistor 802 to activate the transistor 802. The transistor 802 induces a negative bias across the capacitor 128, where the voltage on the terminal of the capacitor 128 that is connected to the transistor 802 is greater than the voltage on the terminal of the capacitor 128 that is connected to the reset transistor 112. This causes the charge stored in the capacitor 128 to be drained. The supply voltage source 114 may be biased low when the reset transistor 112 is off and the transistor 802 is on, and the supply voltage 114 may be biased high when the reset transistor 112 is on and the transistor 802 is off.

The capacitors 128, 606 and 706, and the transistors 802 of the pixel sensors 100 described herein may be included on one or more semiconductor dies of a semiconductor device described herein. For example, as shown in an example implementation 808 in FIG. 8D, which is a variation of the pixel sensor 100 from FIG. 1A, instead of being on the semiconductor die 204, the capacitor 128 may be included on the semiconductor die 202 (e.g., a first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, and the conversion gain transistor 126 may be included on the semiconductor die 204 (e.g., a second semiconductor die), and the image processing circuit 120 may be included on the semiconductor die 252 (e.g., a third semiconductor die).

As another example, as shown in an example implementation 810 in FIG. 8E, which is another variation of the pixel sensor 100 from FIG. 1A, instead of being on the semiconductor die 204, the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, and the conversion gain transistor 126 may be included on the semiconductor die 204 (e.g., the second semiconductor die).

As another example, as shown in an example implementation 812 in FIG. 8F, which is a variation of the pixel sensor 100 in the example implementation 800 from FIG. 8A, instead of being on the semiconductor die 204, the additional transistor 802 and the capacitor 128 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, and the conversion gain transistor 126 may be included on the semiconductor die 204 (e.g., the second semiconductor die), and the image processing circuit 120 may be included on the semiconductor die 252 (e.g., the third semiconductor die).

As another example, as shown in an example implementation 814 in FIG. 8G, which is another variation of the pixel sensor 100 in the example implementation 800 from FIG. 8A, instead of being on the semiconductor die 204, the additional transistor 802 and the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, and the conversion gain transistor 126 may be included on the semiconductor die 204 (e.g., the second semiconductor die).

As another example, as shown in an example implementation 816 in FIG. 8H, which is a variation of the pixel sensor 100 in the example implementation 600 from FIG. 6A, instead of being on the semiconductor die 204, the capacitor 128 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the conversion gain transistor 604, and the capacitor 606 may be included on the semiconductor die 204 (e.g., the second semiconductor die), and the image processing circuit 120 may be included on the semiconductor die 252 (e.g., the third semiconductor die). In some implementations, the capacitors 128 and 606 are on the same semiconductor die.

As another example, as shown in an example implementation 818 in FIG. 8I, which is another variation of the pixel sensor 100 in the example implementation 600 from FIG. 6A, instead of being on the semiconductor die 204, the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the conversion gain transistor 604, and the capacitor 606 may be included on the semiconductor die 204 (e.g., the second semiconductor die). In some implementations, the capacitors 128 and 606 are on the same semiconductor die.

As another example, as shown in an example implementation 820 in FIG. 8J, which is another variation of the pixel sensor 100 in the example implementation 600 from FIG. 6A, instead of being on the semiconductor die 204, the capacitor 606 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the capacitor 128, and the conversion gain transistor 604 may be included on the semiconductor die 204 (e.g., the second semiconductor die), and the image processing circuit 120 may be included on the semiconductor die 252 (e.g., the third semiconductor die). In some implementations, the capacitors 128 and 606 are on the same semiconductor die.

As another example, as shown in an example implementation 822 in FIG. 8K, which is another variation of the pixel sensor 100 in the example implementation 600 from FIG. 6A, instead of being on the semiconductor die 204, the capacitor 606 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the capacitor 128, and the conversion gain transistor 604 may be included on the semiconductor die 204 (e.g., the second semiconductor die). In some implementations, the capacitors 128 and 606 are on the same semiconductor die.

As another example, as shown in an example implementation 824 in FIG. 8L, which is a variation of the pixel sensor 100 in the example implementation 804 from FIG. 8B, instead of being on the semiconductor die 204, the additional transistor 802 and the capacitor 128 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the conversion gain transistor 604, and the capacitor 606 may be included on the semiconductor die 204 (e.g., the second semiconductor die), and the image processing circuit 120 may be included on the semiconductor die 252 (e.g., the third semiconductor die). In some implementations, the additional transistor 802, capacitor 128, and capacitor 606 are on the same semiconductor die.

As another example, as shown in an example implementation 826 in FIG. 8M, which is another variation of the pixel sensor 100 in the example implementation 804 from FIG. 8B, instead of being on the semiconductor die 204, the additional transistor 802 and the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the conversion gain transistor 604, and the capacitor 606 may be included on the semiconductor die 204 (e.g., the second semiconductor die). In some implementations, the additional transistor 802, capacitor 128, and capacitor 606 are on the same semiconductor die.

As another example, as shown in an example implementation 828 in FIG. 8N, which is another variation of the pixel sensor 100 in the example implementation 804 from FIG. 8B, instead of being on the semiconductor die 204, the capacitor 606 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the capacitor 128, the conversion gain transistor 604, and the additional transistor 802 may be included on the semiconductor die 204 (e.g., the second semiconductor die), and the image processing circuit 120 may be included on the semiconductor die 252 (e.g., the third semiconductor die). In some implementations, the additional transistor 802, capacitor 128, and capacitor 606 are on the same semiconductor die.

As another example, as shown in an example implementation 830 in FIG. 8O, which is another variation of the pixel sensor 100 in the example implementation 804 from FIG. 8B, instead of being on the semiconductor die 204, the capacitor 606 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the capacitor 128, the conversion gain transistor 604, and the additional transistor 802 may be included on the semiconductor die 204 (e.g., the second semiconductor die). In some implementations, the additional transistor 802, capacitor 128, and capacitor 606 are on the same semiconductor die.

As another example, as shown in an example implementation 832 in FIG. 8P, which is a variation of the pixel sensor 100 in the example implementation 700 from FIG. 7A, instead of being on the semiconductor die 204, the capacitor 128 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the conversion gain transistor 704, and the capacitor 706 may be included on the semiconductor die 204 (e.g., the second semiconductor die), and the image processing circuit 120 may be included on the semiconductor die 252 (e.g., the third semiconductor die). In some implementations, the capacitors 128 and 706 are on the same semiconductor die.

As another example, as shown in an example implementation 834 in FIG. 8Q, which is another variation of the pixel sensor 100 in the example implementation 700 from FIG. 7A, instead of being on the semiconductor die 204, the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the conversion gain transistor 704, and the capacitor 706 may be included on the semiconductor die 204 (e.g., the second semiconductor die). In some implementations, the capacitors 128 and 706 are on the same semiconductor die.

As another example, as shown in an example implementation 836 in FIG. 8R, which is another variation of the pixel sensor 100 in the example implementation 700 from FIG. 7A, instead of being on the semiconductor die 204, the capacitor 706 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the capacitor 128, and the conversion gain transistor 704 may be included on the semiconductor die 204 (e.g., the second semiconductor die), and the image processing circuit 120 may be included on the semiconductor die 252 (e.g., the third semiconductor die). In some implementations, the capacitors 128 and 706 are on the same semiconductor die.

As another example, as shown in an example implementation 838 in FIG. 8S, which is another variation of the pixel sensor 100 in the example implementation 700 from FIG. 7A, instead of being on the semiconductor die 204, the capacitor 706 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the capacitor 128, and the conversion gain transistor 704 may be included on the semiconductor die 204 (e.g., the second semiconductor die). In some implementations, the capacitors 128 and 706 are on the same semiconductor die.

As another example, as shown in an example implementation 840 in FIG. 8T, which is a variation of the pixel sensor 100 in the example implementation 806 from FIG. 8C, instead of being on the semiconductor die 204, the additional transistor 802 and the capacitor 128 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the conversion gain transistor 704, and the capacitor 706 may be included on the semiconductor die 204 (e.g., the second semiconductor die), and the image processing circuit 120 may be included on the semiconductor die 252 (e.g., the third semiconductor die). In some implementations, the additional transistor 802, capacitor 128, and capacitor 706 are on the same semiconductor die.

As another example, as shown in an example implementation 842 in FIG. 8U, which is another variation of the pixel sensor 100 in the example implementation 806 from FIG. 8C, instead of being on the semiconductor die 204, the additional transistor 802 and the capacitor 128 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the conversion gain transistor 704, and the capacitor 706 may be included on the semiconductor die 204 (e.g., the second semiconductor die). In some implementations, the additional transistor 802, capacitor 128, and capacitor 706 are on the same semiconductor die.

As another example, as shown in an example implementation 844 in FIG. 8V, which is another variation of the pixel sensor 100 in the example implementation 806 from FIG. 8C, instead of being on the semiconductor die 204, the capacitor 706 may be included on the semiconductor die 202 (e.g., the first semiconductor die) with the photodiode 106, the transfer gate 108, and the first floating diffusion node 110. The reset transistor 112, the source-follower gate 116, the row-select gate 118, the intermediate transistor 122, the second floating diffusion node 124, the conversion gain transistor 126, the capacitor 128, the conversion gain transistor 704, and the additional transistor 802 may be included on the semiconductor die 204 (e.g., the second semiconductor die), and the image processing circuit 120 may be included on the semiconductor die 252 (e.g., the third semiconductor die). In some implementations, the additional transistor 802, capacitor 128, and capacitor 706 are on the same semiconductor die.

As another example, as shown in an example implementation 846 in FIG. 8W, which is another variation of the pixel sensor 100 in the example implementation 806 from FIG. 8C, instead of being on the semiconductor die 204, the capacitor 706 may be included on the semiconductor die 252 (e.g., the third semiconductor die) with the image processing circuit 120. The photodiode 106, the transfer gate 108, and the first floating diffusion node 110 may be included on the semiconductor die 202 (e.g., the first semiconductor die). The reset transistor 112, the source-follower gate 116, the row-select gate 118, the intermediate transistor 122, the second floating diffusion node 124, the conversion gain transistor 126, the capacitor 128, the conversion gain transistor 704, and the additional transistor 802 may be included on the semiconductor die 204 (e.g., the second semiconductor die). In some implementations, the additional transistor 802, capacitor 128, and capacitor 706 are on the same semiconductor die.

As indicated above, FIGS. 8A-8W are provided as examples. Other examples may differ from what is described with regard to FIGS. 8A-8W.

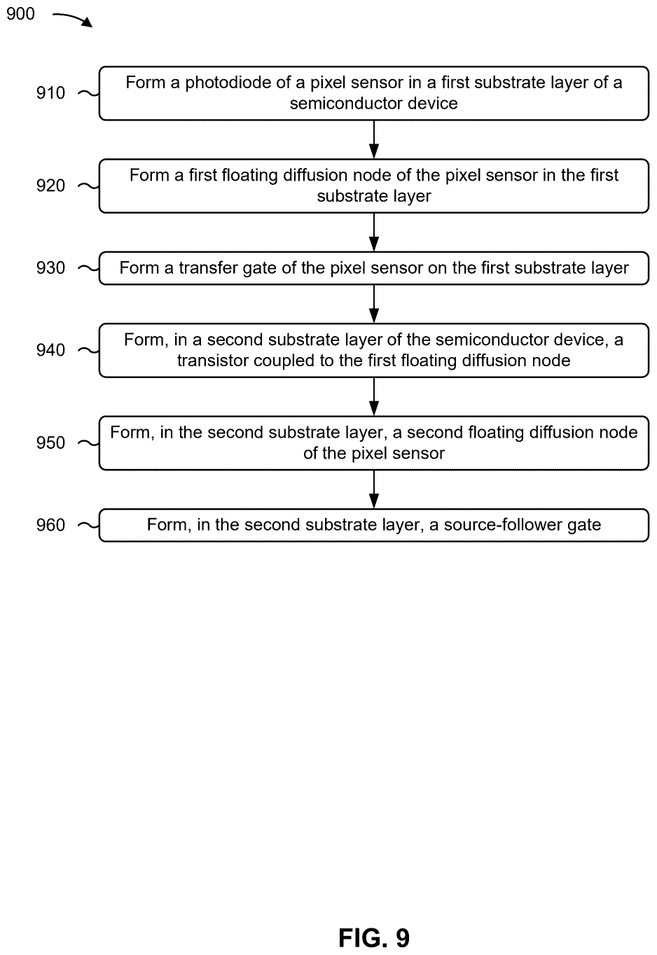

FIG. 9 is a flowchart of an example process 900 associated with forming semiconductor devices. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming a photodiode of a pixel sensor in a first substrate layer of a semiconductor device (block 910). For example, one or more semiconductor processing tools may be used to form a photodiode (e.g., photodiode 106) of a pixel sensor (e.g., pixel sensor 100) in a first substrate layer (e.g., substrate layer 218) of a semiconductor device (e.g. semiconductor device 200, 608, 708), as described herein.

As further shown in FIG. 9, process 900 may include forming a first floating diffusion node of the pixel sensor in the first substrate layer (block 920). For example, one or more semiconductor processing tools may be used to form a first floating diffusion node (e.g., first floating diffusion node 110) of the pixel sensor in the first substrate layer, as described herein.

As further shown in FIG. 9, process 900 may include forming a transfer gate of the pixel sensor on the first substrate layer (block 930). For example, one or more semiconductor processing tools may be used to form a transfer gate (e.g., transfer gate 108) of the pixel sensor on the first substrate layer, as described herein.

As further shown in FIG. 9, process 900 may include forming, in a second substrate layer of the semiconductor device, a transistor coupled to the first floating diffusion node (block 940). For example, one or more semiconductor processing tools may be used to form, in a second substrate layer (e.g., substrate layer 242) of the semiconductor device, a transistor (e.g., intermediate transistor 122) coupled to the first floating diffusion node, as described herein.

As further shown in FIG. 9, process 900 may include forming, in the second substrate layer, a second floating diffusion node of the pixel sensor (block 950). For example, one or more semiconductor processing tools may be used to form, in the second substrate layer, a second floating diffusion node (e.g., second floating diffusion node 124) of the pixel sensor, as described herein. In some implementations, a source/drain region of the transistor includes the second floating diffusion node.

As further shown in FIG. 9, process 900 may include forming, in the second substrate layer, a source-follower gate (block 960). For example, one or more semiconductor processing tools may be used to form, in the second substrate layer, a source-follower gate (e.g., source-follower gate 116), as described herein. In some implementations, the source-follower gate is coupled to the second floating diffusion node.

Process 900 may include additional implementations, such as any single implementation or any combination of implementations described below and/or in connection with one or more other processes described elsewhere herein.

In a first implementation, process 900 includes forming, in an interconnect layer (e.g., interconnect layer 240) of the semiconductor device, a plurality of capacitor structures (e.g., capacitors 128, 606, 706) coupled to the second floating diffusion node in parallel.

In a second implementation, alone or in combination with the first implementation, process 900 includes forming, in the second substrate layer, a first conversion gain transistor (e.g., conversion gain transistor 126), where the first conversion gain transistor is coupled to the second floating diffusion node and a first capacitor structure (e.g., capacitor 128) of the plurality of capacitor structures, and forming, in the second substrate layer, a second conversion gain transistor (e.g., conversion gain transistor 604, 704), where the second conversion gain transistor is coupled to the second floating diffusion node and a second capacitor structure (e.g., capacitor 606, 706) of the plurality of capacitor structures.

In a third implementation, alone or in combination with one or more of the first and second implementations, process 900 includes coupling a source/drain region of the first conversion gain transistor to the second floating diffusion node, and coupling a source/drain region of the first conversion gain transistor to the second floating diffusion node.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

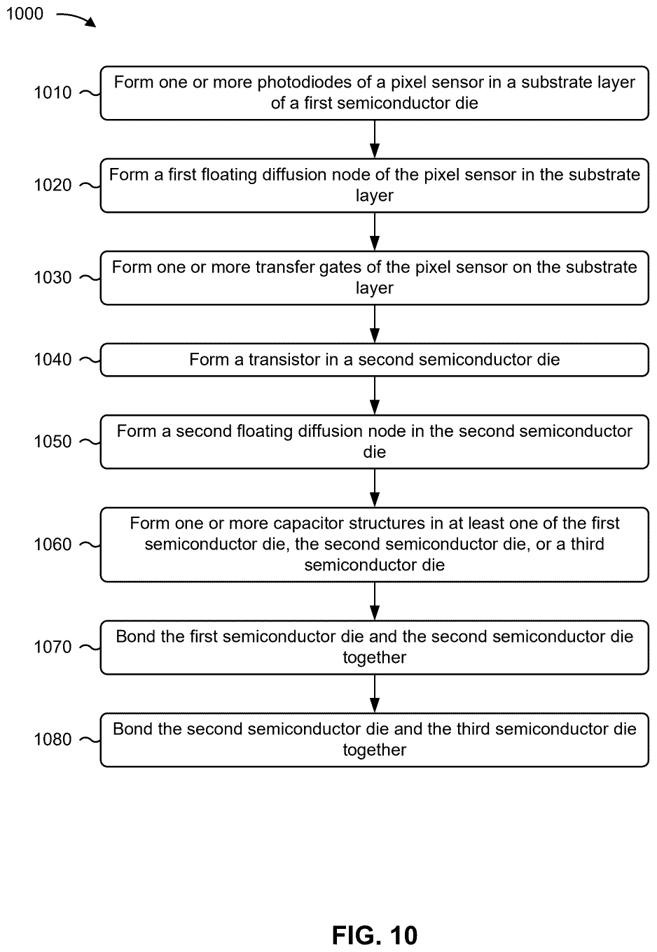

FIG. 10 is a flowchart of an example process 1000 associated with forming semiconductor devices. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming one or more photodiodes of a pixel sensor in a substrate layer of a first semiconductor die (block 1010). For example, one or more semiconductor processing tools may be used to form one or more photodiodes (e.g., photodiode 106) of a pixel sensor (e.g., pixel sensor 100) in a substrate layer (e.g., substrate layer 218) of a first semiconductor die (e.g., semiconductor die 202), as described herein.

As further shown in FIG. 10, process 1000 may include forming a first floating diffusion node of the pixel sensor in the substrate layer (block 1020). For example, one or more semiconductor processing tools may be used to form a first floating diffusion node (e.g., first floating diffusion node 110) of the pixel sensor in the substrate layer, as described herein.

As further shown in FIG. 10, process 1000 may include forming one or more transfer gates of the pixel sensor on the substrate layer (block 1030). For example, one or more semiconductor processing tools may be used to form one or more transfer gates (e.g., transfer gate 108) of the pixel sensor on the substrate layer, as described herein.

As further shown in FIG. 10, process 1000 may include forming a transistor in a second semiconductor die (block 1040). For example, one or more semiconductor processing tools may be used to form a transistor (e.g., intermediate transistor 122) in a second semiconductor die (e.g., semiconductor die 204), as described herein. In some implementations, the transistor is coupled to the first floating diffusion node.

As further shown in FIG. 10, process 1000 may include forming a second floating diffusion node in the second semiconductor die (block 1050). For example, one or more semiconductor processing tools may be used to form a second floating diffusion node (e.g., second floating diffusion node 124) in the second semiconductor die, as described herein. In some implementations, a first source/drain terminal of the transistor is coupled to the first floating diffusion node. In some implementations, a second source/drain terminal of the transistor is coupled to the second floating diffusion node.

As further shown in FIG. 10, process 1000 may include forming one or more capacitor structures in at least one of the first semiconductor die, the second semiconductor die, or a third semiconductor die (block 1060). For example, one or more semiconductor processing tools may be used to form one or more capacitor structures (e.g., capacitor 128, 606, 706) in at least one of the first semiconductor die, the second semiconductor die, or a third semiconductor die (e.g., semiconductor die 252), as described herein.

As further shown in FIG. 10, process 1000 may include bonding the first semiconductor die and the second semiconductor die together (block 1070). For example, one or more semiconductor processing tools may be used to bond the first semiconductor die and the second semiconductor die together, as described herein.

As further shown in FIG. 10, process 1000 may include bonding the second semiconductor die and the third semiconductor die together (block 1080). For example, one or more semiconductor processing tools may be used to bond the second semiconductor die and the third semiconductor die together, as described herein. In some implementations, the one or more capacitor structures are coupled to the second floating diffusion node.

Process 1000 may include additional implementations, such as any single implementation or any combination of implementations described below and/or in connection with one or more other processes described elsewhere herein.

In a first implementation, process 1000 includes forming a source-follower gate (e.g., source-follower gate 116) in the second semiconductor die, where the source-follower gate is coupled to the second floating diffusion node.

In a second implementation, alone or in combination with the first implementation, process 1000 includes forming a first conversion gain transistor (e.g., conversion gain transistor 126) in another substrate layer (e.g., substrate layer 242) of the second semiconductor die, where a first capacitor structure (e.g., capacitor 128) of the one or more capacitor structures is coupled to the first conversion gain transistor, and forming a second conversion gain transistor (e.g., conversion gain transistor 604, 704) in the substrate layer of the second semiconductor die, where a second capacitor structure (e.g., capacitor 606, 706) of the one or more capacitor structures is coupled to the second conversion gain transistor, and where forming the one or more capacitor structures includes forming the first capacitor structure in the first semiconductor die, in the second semiconductor die, or in the third semiconductor die, and forming the second capacitor structure in the first semiconductor die, in the second semiconductor die, or in the third semiconductor die.

In a third implementation, alone or in combination with one or more of the first and second implementations, the first capacitor structure and the second capacitor structure are in different semiconductor dies.

In a fourth implementation, alone or in combination with one or more of the first through third implementations, a source/drain terminal of the first conversion gain transistor is coupled to a source/drain terminal of the second conversion gain transistor, where the second capacitor structure is coupled to the source/drain terminal of the second conversion gain transistor.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a pixel sensor includes a transistor between a transfer transistor on a first semiconductor die and the source-follower gate on a second semiconductor die. The arrangement of the transistor between the transfer transistor and the source-follower gate may reduce input capacitance to the source-follower gate, which results in increased conversion gain in low-lighting conditions (e.g., high conversion gain mode) of a multiple semiconductor die CMOS image sensor device. In more detail, a transistor between a first floating diffusion node coupled to the transfer transistor, and a second floating diffusion node coupled to the source-follower gate may be turned off during signal readout from the source-follower gate, which blocks the signal path between the transistor and the transfer transistor. This prevents parasitic capacitance from the signal path from delaying and/or reducing the discharge of photocurrent from the second floating diffusion node onto the source-follower gate. As a result, substantially the full magnitude of the photocurrent can be applied to the source-follower gate, as opposed to the parasitic capacitance from the signal path between the transistor and the transfer transistor causing a reduced amount of photocurrent being applied to the source-follower gate. This enables higher readout signal voltages to be achieved, thereby increasing the conversion gain. Pixel sensors including the transistor arrangement may experience reduced input capacitance to the source-follower gate, allowing for longer integration times for the pixel sensor and faster response times during signal readout from the source-follower gate, which may increase conversion gain in dynamic and low-lighting conditions in comparison to when the input capacitance is greater.

As described in greater detail above, some implementations described herein provide a semiconductor device. The semiconductor device includes one or more photodiodes in a substrate layer of the semiconductor device. The semiconductor device includes a transfer gate coupled to the one or more photodiodes. The semiconductor device includes a first floating diffusion node coupled to the transfer gate. The semiconductor device includes a transistor coupled to the first floating diffusion node. The semiconductor device includes a second floating diffusion node coupled to the transistor, where the transistor is coupled between the first floating diffusion node and the second floating diffusion node. The semiconductor device includes a source-follower gate coupled to the second floating diffusion node.

As described in greater detail above, some implementations described herein provide a method. The method includes forming a photodiode of a pixel sensor in a first substrate layer of a semiconductor device. The method includes forming a first floating diffusion node of the pixel sensor in the first substrate layer. The method includes forming a transfer gate of the pixel sensor on the first substrate layer. The method includes forming, in a second substrate layer of the semiconductor device, a transistor coupled to the first floating diffusion node. The method includes forming, in the second substrate layer, a second floating diffusion node of the pixel sensor, where a source/drain region of the transistor includes the second floating diffusion node. The method includes forming, in the second substrate layer, a source-follower gate, where the source-follower gate is coupled to the second floating diffusion node.

As described in greater detail above, some implementations described herein provide a method. The method includes forming one or more photodiodes of a pixel sensor in a substrate layer of a first semiconductor die. The method includes forming a first floating diffusion node of the pixel sensor in the substrate layer. The method includes forming one or more transfer gates of the pixel sensor on the substrate layer. The method includes forming a transistor in a second semiconductor die, where the transistor is coupled to the first floating diffusion node. The method includes forming a second floating diffusion node in the second semiconductor die, where a first source/drain terminal of the transistor is coupled to the first floating diffusion node, and where a second source/drain terminal of the transistor is coupled to the second floating diffusion node. The method includes forming one or more capacitor structures in at least one of the first semiconductor die, the second semiconductor die, or a third semiconductor die. The method includes bonding the first semiconductor die and the second semiconductor die together. The method includes bonding the second semiconductor die and the third semiconductor die together, where the one or more capacitor structures are coupled to the second floating diffusion node.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more photodiodes in a substrate layer of the semiconductor device;
a transfer gate coupled to the one or more photodiodes;
a first floating diffusion node coupled to the transfer gate;
a transistor coupled to the first floating diffusion node;
a second floating diffusion node coupled to the transistor,
wherein the transistor is coupled between the first floating diffusion node and the second floating diffusion node; and
a source-follower gate coupled to the second floating diffusion node.

2. The semiconductor device of claim 1, further comprising a capacitor structure coupled to the second floating diffusion node.

3. The semiconductor device of claim 2, further comprising a conversion gain transistor coupled to the second floating diffusion node and to the capacitor structure.

4. The semiconductor device of claim 2, wherein the second floating diffusion node is included on a first semiconductor die of the semiconductor device, and
wherein the capacitor structure is included on a second semiconductor die of the semiconductor device.

5. The semiconductor device of claim 1, further comprising a plurality of capacitor structures coupled to the second floating diffusion node in parallel.

6. The semiconductor device of claim 5, further comprising:
a first conversion gain transistor coupled to the second floating diffusion node and a first capacitor structure of the plurality of capacitor structures; and
a second conversion gain transistor coupled to the second floating diffusion node and a second capacitor structure of the plurality of capacitor structures.

7. The semiconductor device of claim 6, wherein the first capacitor structure is included on a first semiconductor die of the semiconductor device, and
wherein the second capacitor structure is included on a second semiconductor die of the semiconductor device.

8. The semiconductor device of claim 6, wherein a first source/drain terminal of the first conversion gain transistor is coupled to a first source/drain terminal of the second conversion gain transistor.

9. The semiconductor device of claim 8, wherein the first source/drain terminal of the second conversion gain transistor is coupled to the second capacitor structure, and
wherein a second source/drain terminal of the second conversion gain transistor is coupled to the second floating diffusion node.

10. The semiconductor device of claim 8, wherein a second source/drain terminal of the first conversion gain transistor is coupled to the first capacitor structure.

11. The semiconductor device of claim 8, wherein a source/drain terminal of the transistor comprises the second floating diffusion node.

12. A method, comprising:
forming a photodiode of a pixel sensor in a first substrate layer of a semiconductor device;
forming a first floating diffusion node of the pixel sensor in the first substrate layer;
forming a transfer gate of the pixel sensor on the first substrate layer;
forming, in a second substrate layer of the semiconductor device, a transistor coupled to the first floating diffusion node;
forming, in the second substrate layer, a second floating diffusion node of the pixel sensor,
wherein a source/drain region of the transistor comprises the second floating diffusion node; and
forming, in the second substrate layer, a source-follower gate,
wherein the source-follower gate is coupled to the second floating diffusion node.

13. The method of claim 12, further comprising forming, in an interconnect layer of the semiconductor device, a plurality of capacitor structures coupled to the second floating diffusion node in parallel.

14. The method of claim 13, further comprising:
forming, in the second substrate layer, a first conversion gain transistor,
wherein the first conversion gain transistor is coupled to the second floating diffusion node and a first capacitor structure of the plurality of capacitor structures; and
forming, in the second substrate layer, a second conversion gain transistor,
wherein the second conversion gain transistor is coupled to the second floating diffusion node and a second capacitor structure of the plurality of capacitor structures.

15. The method of claim 14, further comprising:
coupling a source/drain region of the first conversion gain transistor to the second floating diffusion node; and
coupling a source/drain region of the first conversion gain transistor to the second floating diffusion node.

16. A method, comprising:
forming one or more photodiodes of a pixel sensor in a substrate layer of a first semiconductor die;
forming a first floating diffusion node of the pixel sensor in the substrate layer;
forming one or more transfer gates of the pixel sensor on the substrate layer;
forming a transistor in a second semiconductor die,
wherein the transistor is coupled to the first floating diffusion node;
forming a second floating diffusion node in the second semiconductor die,
wherein a first source/drain terminal of the transistor is coupled to the first floating diffusion node, and
wherein a second source/drain terminal of the transistor is coupled to the second floating diffusion node;
forming one or more capacitor structures in at least one of the first semiconductor die, the second semiconductor die, or a third semiconductor die;
bonding the first semiconductor die and the second semiconductor die together; and
bonding the second semiconductor die and the third semiconductor die together,
wherein the one or more capacitor structures are coupled to the second floating diffusion node.

17. The method of claim 16, further comprising forming a source-follower gate in the second semiconductor die,
wherein the source-follower gate is coupled to the second floating diffusion node.

18. The method of claim 16, further comprising:
forming a first conversion gain transistor in another substrate layer of the second semiconductor die,
wherein a first capacitor structure of the one or more capacitor structures is coupled to the first conversion gain transistor; and
forming a second conversion gain transistor in the substrate layer of the second semiconductor die,
wherein a second capacitor structure of the one or more capacitor structures is coupled to the second conversion gain transistor, and
wherein forming the one or more capacitor structures comprises:
forming the first capacitor structure in the first semiconductor die, in the second semiconductor die, or in the third semiconductor die; and
forming the second capacitor structure in the first semiconductor die, in the second semiconductor die, or in the third semiconductor die.

19. The method of claim 18, wherein the first capacitor structure and the second capacitor structure are in different semiconductor dies.

20. The method of claim 18, wherein a source/drain terminal of the first conversion gain transistor is coupled to a source/drain terminal of the second conversion gain transistor, and
wherein the second capacitor structure is coupled to the source/drain terminal of the second conversion gain transistor.
